(19) United States
(12) Patent Application Publication
(10) Pub. No.: US 2025/0143087 A1
(43) Pub. Date: May 1, 2025

(54) DISPLAY PANEL, DISPLAY APPARATUS, AND METHOD FOR MANUFACTURING DISPLAY PANEL

(71) Applicants: KunShan Go-Visionox Opto-Electronics Co., Ltd, Kunshan (CN); Hefei Visionox Technology Co., Ltd., Hefei (CN)

(72) Inventors: Chung-Chun LEE, Kunshan (CN); Haohan ZHANG, Kunshan (CN); Yuan YAO, Kunshan (CN)

(73) Assignees: KunShan Go-Visionox Opto-Electronics Co., Ltd, Kunshan (CN); Hefei Visionox Technology Co., Ltd., Hefei (CN)

(21) Appl. No.: 18/610,872

(22) Filed: Mar. 20, 2024

(30) Foreign Application Priority Data
Oct. 25, 2023 (CN) 202311395352.7
Mar. 15, 2024 (CN) 202410302679.3

(51) Int. Cl. H10K 59/122; H10K 59/35

(52) U.S. Cl. CPC H10K 59/122; H10K 59/353; H10K 59/352

(57) ABSTRACT

A display panel including a display base, in which the display base includes a first display area including a plurality of first sub-pixels arranged in an array in a first direction, the first sub-pixel includes at least two sub-pixel blocks; and in the first sub-pixel, at least two of the sub-pixel blocks are adjacent and separated by an isolation structure.

### CROSS REFERENCE TO RELATED APPLICATION

The present application claims priority to Chinese Patent Application No. 202311395352.7 filed on Oct. 25, 2023, and titled “DISPLAY PANEL AND DISPLAY APPARATUS”, and Chinese Patent Application No. 202410302679.3 filed on Mar. 15, 2024, and titled “DISPLAY PANEL, DISPLAY APPARATUS, AND METHOD FOR MANUFACTURING DISPLAY PANEL”, both of which are incorporated herein by reference in their entireties.

### TECHNICAL FIELD

The present application relates to the field of display technology, and particularly to a display panel, a display apparatus, and a method for manufacturing a display panel.

### BACKGROUND

Organic Light-Emitting Diode (OLED) is an organic thin film electroluminescent device, which has gained great attention and been widely used in electronic display products due to its simple manufacture process, low cost, low power consumption, high brightness, wide viewing angle, high contrast and flexible display.

However, the current electronic display products are limited by their own structure design, which makes it difficult to achieve both good touch control and display functions when the electronic display products are applied in scenarios such as under-screen recognition and transparent display.

### SUMMARY

A first aspect of the present application provides a display panel including a display base, in which the display base includes a first display area including a plurality of first sub-pixels arranged in an array in a first direction, the first sub-pixel includes at least two sub-pixel blocks; and in the first sub-pixel, at least two of the sub-pixel blocks are adjacent and separated by an isolation structure.

In actual process, debris may intrude into the first sub-pixel and cause poor light emission in the first sub-pixel. In the above solution, by dividing the first sub-pixel into a plurality of sub-pixel blocks, debris may cause poor light emission in only one of the sub-pixel blocks, while the first sub-pixel itself can still emit light, thereby reducing the risk that hazardous substances such as debris intrude into the first sub-pixel and cause display malfunction in the display panel.

In an implementation of the first aspect of the present application, the display panel further includes a base and a display function layer located on the base in a second direction, in which the display function layer includes a plurality of light-emitting devices, and each of the sub-pixel blocks is provided with one of the light-emitting devices; the light-emitting device includes a first electrode, a light-emitting function layer, and a second electrode sequentially stacked on the base, and in a same first sub-pixel, the first electrodes respectively corresponding to adjacent sub-pixel blocks are electrically connected to each other; the isolation structure is located on the base and defines a plurality of isolation openings, and the light-emitting devices are respectively disposed in the isolation openings.

In the above solutions, the first electrodes of two light-emitting devices in the same first sub-pixel are electrically connected to each other, so that the driving manner for the entirety of the pixels is not changed; and the application of the isolation structure may result in that the manufacturing process of the light-emitting device requires no mask plate, and thus it is not necessary to consider the alignment accuracy of the manufacturing process, which is beneficial to reducing the gap size of the light-emitting device so as to increase the pixel arrangement density PPI of the display panel.

In an implementation of the first aspect of the present application, the isolation structure includes a support portion and a crown portion sequentially stacked on the base, an orthographic projection of the support portion on the base is located within an orthographic projection of the crown portion on the base, and the support portion includes a conductive structure, and the second electrode of the light-emitting device is located in a corresponding one of the isolation openings and connected to the support portion.

In the above solutions, at the gap between adjacent light-emitting devices, the isolation structure is generally presented as wide on the top and narrow on the bottom, and thus during the manufacturing of the light-emitting device, the isolation effect of the isolation structure on the light-emitting function layer can be enhanced, so as to reduce the current crosstalk between adjacent light-emitting devices.

Optionally, for example, the support portion and the crown portion are integrally manufactured.

Optionally, for example, the support portion and the crown portion are of different materials. Further optionally, for example, the support portion and the crown portion each include a conductive structure.

In an implementation of the first aspect of the present application, the base may further include: a pixel defining layer located at a side of the isolation structure close to the base, i.e., between the base and the isolation structure, and including a plurality of pixel openings respectively corresponding to the isolation openings; in which the pixel opening accommodates the light-emitting device and exposes the first electrode, the pixel openings are respectively corresponding to the isolation openings, and the pixel opening is communicated to a corresponding one of the isolation openings.

In an implementation of the first aspect of the present application, in the first sub-pixel, an orthographic projection of the pixel openings corresponding to at least two of the sub-pixel blocks on the base is located within an orthographic projection of a same isolation opening on the base; or an orthographic projection of the pixel opening corresponding to each of the sub-pixel blocks on the base is located within an orthographic projection of the isolation opening on the base.

In an implementation of the first aspect of the present application, an orthographic projection of a gap between two adjacent first electrodes on the base is located within an orthographic projection of the support portion on the base to overlap edges of the first electrodes with edges of the support portion to form a capacitor, and the pixel defining layer covers the edges of the first electrodes to separate the support portion and the first electrodes.

The light-emitting device is less bright when activated at a lower voltage, which results in poor visual effect, and in the presence of leakage currents, the light-emitting device may emit light even at a low gray scale (e.g., a dark state), i.e., it cannot be turned off. However, in the above solutions, with the capacitor formed by the edge portions of the support portion and the first electrodes, the light-emitting device can be charged in the activating phase to increase the activating voltage of the light-emitting device, so as to enable the light-emitting device to satisfy the preset brightness requirement when emitting light. In addition, this design can further prevent the light-emitting device from emitting light at a low gray scale.

Optionally, for example, the pixel defining layer is an inorganic layer. The thickness of the inorganic layer is small, so as to ensure that the capacitor that can be formed between the edges of the first electrodes and the edges of the support portion has sufficient electric capacity.

In an implementation of the first aspect of the present application, the isolation structure extends continuously between two adjacent sub-pixel blocks to block light between the two adjacent sub-pixel blocks by the isolation structure.

In an implementation of the first aspect of the present application, in the first display area, the isolation structure further defines a plurality of light-transmitting openings located between the sub-pixel blocks that are adjacent to each other in a same first sub-pixel.

In the above solutions, by arranging the light-transmitting openings in the isolation structure, the area of the display panel in which the light-transmitting openings are arranged can be light-transmitting, so that the area of the display panel in which the light-transmitting openings can achieve transparent display or under-screen recognition functions such as fingerprint recognition and under-screen photography.

In an implementation of the first aspect of the present application, the display panel may further include a touch control structure located at a light-emitting side of the base and including a plurality of touch control electrodes formed as a mesh, and an orthographic projection of a mesh line of the mesh of the touch control electrode on the base is located in a gap between first sub-pixels.

In the above solutions, the light-transmitting openings for transmitting light are arranged at the inner side of the first sub-pixel, so as to reduce the length of the light-transmitting opening adjacent to the mesh line or avoid the light-transmitting opening from being adjacent to the mesh line, which can reduce signal interference of the touch control function and the display function when they are driven.

In an implementation of the first aspect of the present application, an orthographic projection of the first electrode on the base is located outside an orthographic projection of the light-transmitting opening on the base, a wire is arranged in the base, and in the first sub-pixel with the sub-pixel blocks, the first electrodes of the light-emitting devices corresponding to two adjacent sub-pixel blocks are connected to each other via the wire. In this design, the first electrode is arranged away from the light-transmitting opening, so that the light transmittance of the display panel at the light-transmitting opening can be increased, thereby increasing the light transmittance of the first display area.

In another implementation of the first aspect of the present application, in the first sub-pixel, the light-emitting devices corresponding to two adjacent sub-pixel blocks share the first electrode. For example, at the location where the light-transmitting opening is located, the first electrode may be provided with a via overlapping the light-transmitting opening to avoid blocking the light emitted into the light-transmitting opening.

In another implementation of the first aspect of the present application, the first electrode includes a reflective electrode layer and a transparent electrode layer stacked on the base, and the reflective electrode layer is located between the base and the transparent electrode layer; in the first sub-pixel with the sub-pixel blocks, the first electrodes of the light-emitting devices in the sub-pixel blocks are connected via the transparent electrode layer, and the orthographic projection of the light-transmitting opening on the base is located within an orthographic projection of the transparent electrode layer on the base. This design enables that the arrangement of the isolation opening will not increase the difficulty of the manufacturing process of the display base and will not affect the distribution of the circuits in the base.

In an implementation of the first aspect of the present application, the first sub-pixel emits light of at least one color elected from red, green, or blue.

In an implementation of the first aspect of the present application, the first sub-pixel is a first-color sub-pixel emitting light of one color. The first display area further includes a plurality of second-color sub-pixels and a plurality of third-color sub-pixels that are arranged in an array in the first direction, in which every adjacent first-color sub-pixel, second-color sub-pixel, and third-color sub-pixel constitute a pixel. In each pixel, the first-color sub-pixel is located between the second-color sub-pixel and the third-color sub-pixel, the first-color sub-pixel, the second-color sub-pixel, and the third-color sub-pixel emit lights of different colors, and the second-color sub-pixel and the third-color sub-pixel each include a continuous structure. Optionally, for example, along a direction from the second-color sub-pixel to the third-color sub-pixel, the width of the first-color sub-pixel is equal to the width of the light-transmitting opening. Optionally, for example, the wavelengths of the lights emitted by the second-color sub-pixel, the first-color sub-pixel, and the third-color sub-pixel decrease successively. Optionally, for example, the second-color sub-pixel, the first-color sub-pixel, and the third-color sub-pixel emit red light, green light, and blue light, respectively.

In the above solutions, the light-transmitting opening is spaced apart from the mesh lines by the sub-pixel blocks, the second-color sub-pixel, and the third-color sub-pixel, and thus the light-transmitting opening is not adjacent to the mesh lines, so as to significantly reduce the mutual interference between the touch control function and the display function when they are driven.

In another implementation of the first aspect of the present application, the first sub-pixel is categorized as at least a first-color sub-pixel and a second-color sub-pixel that emit lights of two colors, respectively. The first display area further includes a plurality of third-color sub-pixels arranged in an array in the first direction, in which every adjacent first-color sub-pixel, second-color sub-pixel, and third-color sub-pixel constitute a pixel. In each pixel, the second-color sub-pixel is located between the first-color sub-pixel and the third-color sub-pixel, and the third-color sub-pixel includes a continuous structure. Optionally, for example, in each pixel, the light-transmitting openings corresponding to the first-color sub-pixel and the second-color sub-pixel are communicated to each other. Optionally, for example, at a side of the first-color sub-pixel away from the second-color sub-pixel, a distance from the light-transmitting opening to the mesh line is greater than a distance from the first-color sub-pixel to the mesh line. Optionally, for example, the wavelengths of the lights emitted by the first-color sub-pixel, the second-color sub-pixel, and the third-color sub-pixel decrease successively. Optionally, for example, the first-color sub-pixel, the second-color sub-pixel, and the third-color sub-pixel emit red light, green light, and blue light, respectively.

In the above solutions, the light-transmitting opening can have a larger design area (the number of the light-transmitting openings increases), so that the area where the light-transmitting openings are located has a greater light transmittance; furthermore, in this design, the light-transmitting opening is adjacent to the mesh line with a small length and a large spacing, and thus the mutual interference between the touch function and the display function when they are driven can be reduced.

In another implementation of the first aspect of the present application, the first sub-pixel is categorized as at least a first-color sub-pixel, a second-color sub-pixel, and a third-color sub-pixel that emit lights of three colors, respectively. Every adjacent first-color sub-pixel, second-color sub-pixel, and third-color sub-pixel constitute a pixel, and in each pixel, the second-color sub-pixel is located between the first-color sub-pixel and the third-color sub-pixel. Optionally, for example, in each pixel, the light-transmitting openings corresponding to the first-color sub-pixel, the second-color sub-pixel, and the third-color sub-pixel are communicated to each other. Optionally, for example, at a side of the first-color sub-pixel away from the second-color sub-pixel, a distance from the light-transmitting opening to the mesh line is greater than a distance from the first-color sub-pixel to the mesh line, and at a side of the third-color sub-pixel away from the second-color sub-pixel, a distance from the light-transmitting opening to the mesh line is greater than a distance from the third-color sub-pixel to the mesh line. Optionally, for example, the wavelengths of the lights emitted by the first-color sub-pixel, the second-color sub-pixel, and the third-color sub-pixel decrease successively. Optionally, for example, the first-color sub-pixel, the second-color sub-pixel, and the third-color sub-pixel emit red light, green light, and blue light, respectively.

In the above solutions, the light-transmitting opening can have a larger design area (the number of the light-transmitting openings increases), so that the area where the light-transmitting openings are located has a greater light transmittance; furthermore, in this design, the light-transmitting opening is adjacent to the mesh line with a small length and a large spacing, and thus the mutual interference between the touch function and the display function when they are driven can be reduced.

In an implementation of the first aspect of the present application, the touch control electrode includes a plurality of mesh holes enclosed by mesh lines and corresponding to the sub-pixels in one-to-one correspondence, the sub-pixel is located within an orthographic projection of a corresponding one of the mesh holes on the base. Furthermore, for example, a centroid of the orthographic projection of the mesh hole on the base coincides with a centroid of the corresponding sub-pixel. This design can reduce brightness difference of the lights emitted by the sub-pixels at the same viewing angle and in different directions, so as to mitigate color deviation.

In another implementation of the first aspect of the present application, the touch control electrode includes a plurality of mesh holes enclosed by mesh lines and corresponding to the first sub-pixels in one-to-one correspondence, the first sub-pixel is located within an orthographic projection of a corresponding one of the mesh holes on the base. Furthermore, for example, a centroid of the orthographic projection of the mesh hole on the base coincides with a centroid of the corresponding pixel. This design can reduce brightness difference of the lights emitted by the first sub-pixels at the same viewing angle and in different directions, so as to mitigate color deviation.

Optionally, for example, the touch control electrode includes a plurality of first electrode strips that are parallel to each other and a plurality of second electrode strips that are parallel to each other, the first electrode strips and the second electrode strips intersect and are arranged as the mesh of the touch control electrode.

In an implementation of the first aspect of the present application, the entirety of the display area is the first display area. In this design, the display panel may be used in scenarios such as transparent display.

In another implementation of the first aspect of the present application, the display area further includes a second display area located at one side of the first display area, a light transmittance of the first display area is greater than a light transmittance of the second display area. For example, the second display area is a non-light-transmitting area. In this design, the display panel may be used in scenarios such as fingerprint recognition or under-screen photography.

In another implementation of the first aspect of the present application, the first sub-pixel includes a first-color sub-pixel, a second-color sub-pixel, and a third-color sub-pixel that are spaced apart from each other and of different colors, and the first-color sub-pixel, the second-color sub-pixel, and the third-color sub-pixel are arranged adjacently.

In another implementation of the first aspect of the present application, the second-color sub-pixel is located at one side of the first-color sub-pixel in a second direction, the third-color sub-pixel is located at one side of the first-color sub-pixel in the first direction, and the first direction is intersected with the second direction.

In another implementation of the first aspect of the present application, in the first direction, the first-color sub-pixel and the second-color sub-pixel are of a same length and have two flush side edges to form a rectangular structure.

In another implementation of the first aspect of the present application, in the first direction, the first-color sub-pixel, the second-color sub-pixel, and the third-color sub-pixel are of a same length.

In another implementation of the first aspect of the present application, the first-color sub-pixel, the second-color sub-pixel, and the third-color sub-pixel are long strip in shape and sequentially arranged at intervals in the first direction.

In another implementation of the first aspect of the present application, in a second direction intersecting the first direction, the first-color sub-pixel, the second-color sub-pixel, and the third-color sub-pixel are of a same length and have two flush side edges to form a rectangular structure.

In another implementation of the first aspect of the present application, the first sub-pixel includes at least three sub-pixel blocks, and a plurality of the sub-pixel blocks are arranged circularly.

In another implementation of the first aspect of the present application, in the first sub-pixel, for a same sub-pixel block, at least one of the sub-pixel blocks is arranged at each side of the sub-pixel block in the first direction and the second direction.

In another implementation of the first aspect of the present application, the isolation structure extends along the first direction and the second direction, and the first sub-pixel separates, through the isolation structure, the sub-pixel blocks that are adjacent in the first direction and/or the sub-pixel blocks that are adjacent in the second direction.

In another implementation of the first aspect of the present application, the first-color sub-pixel includes a sub-pixel blocks, the second-color sub-pixel includes b sub-pixel blocks, the third-color sub-pixel includes c sub-pixel blocks, and a, b, and c satisfy a≥b≥c.

In another implementation of the first aspect of the present application, the first sub-pixel includes two sub-pixel blocks arranged at intervals along the first direction.

In another implementation of the first aspect of the present application, in the second direction, the two sub-pixel blocks are of a same length and have two flush side edges to form a rectangular structure.

In another implementation of the first aspect of the present application, the first sub-pixel includes a first sub-pixel block, a second sub-pixel block, and a third sub-pixel block, the first sub-pixel block and the second sub-pixel block are located at one side of the third sub-pixel block in the first direction, and the first sub-pixel block and the second sub-pixel block are arranged at intervals in the second direction.

In another implementation of the first aspect of the present application, in the first direction, the first sub-pixel block and the second sub-pixel block are of a same length and have two flush side edges to form a rectangular structure.

In another implementation of the first aspect of the present application, in the first direction, the first sub-pixel block, the second sub-pixel block, and the third sub-pixel block are of a same length.

In another implementation of the first aspect of the present application, in the second direction, a side edge of the first sub-pixel block away from the second sub-pixel block is flush with one side edge of the third sub-pixel block.

In another implementation of the first aspect of the present application, in the second direction, a side edge of the second sub-pixel block away from the first sub-pixel block is flush with one side edge of the third sub-pixel block.

In another implementation of the first aspect of the present application, the first sub-pixel includes four sub-pixel blocks arranged circularly.

In another implementation of the first aspect of the present application, in the first direction and/or the second direction, at least two adjacent sub-pixel blocks are of a same length and have two flush side edges to form a rectangular structure.

In another implementation of the first aspect of the present application, in the first sub-pixel, orthographic projections of at least two of the sub-pixel blocks on a base are of a same size.

In another implementation of the first aspect of the present application, an orthographic projection of at least one of the sub-pixel blocks of the first-color sub-pixel on the base has the same size as an orthographic projection of one of the sub-pixel blocks of the second-color sub-pixel on the base.

In another implementation of the first aspect of the present application, an orthographic projection of the first sub-pixel on the base is a polygon in shape, the polygon includes a plurality of corner areas, and at least one of the corner areas is provided with the sub-pixel block.

In another implementation of the first aspect of the present application, an orthographic projection of the sub-pixel block on the base includes straight edges and/or curved edges.

In another implementation of the first aspect of the present application, at least two of the straight edges are perpendicular to form a right angle.

In another implementation of the first aspect of the present application, for at least two adjacent sub-pixel blocks, the right angles of the two sub-pixel blocks are arranged away from each other.

A second aspect of the present application provides a display panel including: a first display area; a plurality of first sub-pixels arranged in an array in a first direction and disposed in the first display area, and the first sub-pixel including at least two sub-pixel blocks that are spaced apart from each other; a base; and a pixel defining layer located at a side of the base and including a plurality of pixel openings, and a plurality of light-emitting devices of the sub-pixel blocks being located within the pixel openings; in which in the first sub-pixel, at least two of the sub-pixel blocks are adjacent and separated by the pixel defining layer.

In an implementation of the second aspect of the present application, the display panel further comprises: an isolation structure located at a side of the pixel defining layer away from the base and defining a plurality of isolation openings, the light-emitting devices of the sub-pixel blocks being respectively disposed in the isolation openings, the pixel openings being respectively corresponding to the isolation openings, and the pixel opening being communicated to a corresponding one of the isolation openings.

In another implementation of the second aspect of the present application, in the first sub-pixel, at least two of the sub-pixel blocks are adjacent and separated by the isolation structure.

In another implementation of the second aspect of the present application, in the first sub-pixel, an orthographic projection of the pixel openings corresponding to at least two of the sub-pixel blocks on the base is located within an orthographic projection of a same isolation opening on the base; or an orthographic projection of the pixel opening corresponding to each of the sub-pixel blocks on the base is located within an orthographic projection of the isolation opening on the base.

A third aspect of the present application provides a display apparatus, which may include the display panel according to the above first aspect.

In an implementation of the third aspect of the present application, the entirety of the display area in the display panel is the first display area.

In another implementation of the third aspect of the present application, the display area in the display panel includes the first display area and a second display area located at at least one side of the first display area, the first display area is a light-transmitting area, the second display area is a non-light-transmitting area, and the display panel further includes a photosensitive device located at a side of the base away from the touch control structure, and an orthographic projection of the photosensitive device on the base at least partially overlaps the first display area.

A fourth aspect of the present application provides a method for manufacturing a display panel including a first display area, the first display area including a plurality of first sub-pixels arranged in an array in a first direction, the first sub-pixel including at least two sub-pixel blocks, the method including: manufacturing a first electrode and a pixel defining layer on a base sequentially, the pixel defining layer including a plurality of pixel openings for accommodating a light-emitting device and exposing the first electrode; manufacturing an isolation structure at a side of the pixel defining layer away from the base, the isolation structure defining a plurality of isolation openings, the pixel openings being respectively corresponding to and communicated to the isolation openings; manufacturing a light-emitting function layer and a second electrode sequentially at a side of the isolation structure away from the base, the first electrode, the light-emitting function layer, and the second electrode that are sequentially stacked on the base forming a light-emitting device of the sub-pixel block, in which in the first sub-pixel, at least two of the sub-pixel blocks are adjacent and separated by the isolation structure.

In an implementation of the fourth aspect of the present application, the first display area further includes a plurality of second-color sub-pixels and a plurality of third-color sub-pixels that are arranged in an array in the first direction, adjacent first-color sub-pixel, second-color sub-pixel, and third-color sub-pixel constitute a pixel, the method further includes: manufacturing the light-emitting device of the first-color sub-pixel on the base, the first-color sub-pixel including a sub-pixel blocks; manufacturing the light-emitting device of the second-color sub-pixel on the base, the second-color sub-pixel including b sub-pixel blocks, in which a and b satisfy a>b.

In another implementation of the fourth aspect of the present application, after the manufacturing the light-emitting device of the second-color sub-pixel on the base, the method further includes: manufacturing the light-emitting device of the third-color sub-pixel on the base, the third-color sub-pixel including c sub-pixel blocks, in which b and c satisfy b>c.

### BRIEF DESCRIPTION OF THE DRAWINGS

FIG. 1 shows a planar structure schematic diagram of a display panel according to an embodiment of the present application, which illustrates a display base of the display panel.

FIG. 2 shows an enlarged view of area S1 of the display panel as shown in FIG. 1 in a design.

FIG. 3 shows a cross-sectional view of the display panel as shown in FIG. 2 along M1-N1 in a design.

FIG. 4 shows an enlarged view of area S1 of the display panel as shown in FIG. 1 in a design.

FIG. 5 shows a cross-sectional view of the display panel as shown in FIG. 4 along M2-N2 in a design.

FIG. 6 shows a cross-sectional view of the display panel as shown in FIG. 4 along M3-N3.

FIG. 7 shows a cross-sectional view of the display panel as shown in FIG. 2 along M1-N1 in another design.

FIG. 8A shows a planar structure schematic diagram of a touch control electrode in a display panel according to an embodiment of the present application, in which area S2 in FIG. 8A corresponds to area S1 in FIG. 1.

FIG. 8B shows a cross-sectional view of the touch control electrode as shown in FIG. 8A along M4-N4.

FIG. 9A shows a planar structure schematic diagram of a touch control electrode in a display panel according to an embodiment of the present application, in which area S3 in FIG. 9A corresponds to area S1 in FIG. 1.

FIG. 9B shows a cross-sectional view of the touch control electrode as shown in FIG. 9A along M5-N5.

FIG. 10 shows an enlarged view of area S1 of the display panel as shown in FIG. 1 in another design.

FIG. 11 shows an enlarged view of area S1 of the display panel as shown in FIG. 1 in another design.

FIG. 12 shows an enlarged view of area S1 of the display panel as shown in FIG. 1 in another design.

FIG. 13 shows an enlarged view of area S1 of the display panel as shown in FIG. 1 in another design.

FIG. 14 shows an enlarged view of area S1 of the display panel as shown in FIG. 1 in another design.

FIG. 15 shows a cross-sectional view of the display panel as shown in FIG. 4 along M1-N1 in another design.

FIG. 16 shows an enlarged view of a first electrode of the display panel as shown in FIG. 15.

FIG. 17 shows a cross-sectional view of a portion of area of another display panel according to an embodiment of the present application.

FIGS. 18A, 18B, 19A, 19B, 20A, 20B, 21A, 21B, and 22 show process diagrams of a method for manufacturing a display panel according to an embodiment of the present application.

FIG. 23 shows an enlarged view of area S1 of the display panel as shown in FIG. 1 in another design.

FIG. 24 shows an enlarged view of area S1 of the display panel as shown in FIG. 1 in another design.

FIG. 25 shows an enlarged view of area S1 of the display panel as shown in FIG. 1 in another design.

FIG. 26 shows an enlarged view of area S1 of the display panel as shown in FIG. 1 in another design.

FIG. 27 shows a cross-sectional view of the display panel as shown in FIG. 2 along M1-N1 in another design.

FIG. 28 shows a flow diagram of a method for manufacturing a display panel according to an embodiment of the present application.

### DETAILED DESCRIPTION

The technical solutions in the embodiments of the specification will be described clearly and completely below in connection with the accompanying drawings in the embodiments of the specification. Obviously, the described embodiments are only a part of the embodiments of the specification, but not all of the embodiments. Based on the embodiments in the specification, all other embodiments obtained by a person of ordinary skill in the art without inventive effort fall within the scope of protection of the specification.

During the manufacturing of a light-emitting device of a display panel, contaminants such as dust, debris of processing material may enter the opening for accommodating the light-emitting device (e.g., the isolation openings and pixel openings described in the following embodiments), and the contaminants may degrade the light-emitting performance of the light-emitting device or even cause the light-emitting device being quenched when emitting light.

At least one embodiment of the present application provides a display panel to solve at least the above technical problems. The display panel includes a display base, the display base includes a first display area including a plurality of first sub-pixels arranged in an array in a first direction, the first sub-pixel includes at least two sub-pixel blocks and in the first sub-pixel, at least two of the sub-pixel blocks are adjacent and separated by an isolation structure. In the display panel, by dividing the first sub-pixel into a plurality of sub-pixel blocks, debris may cause poor light emission in only one of the sub-pixel blocks, while the first sub-pixel itself can still emit light, thereby reducing the risk that hazardous substances such as debris intrude into the sub-pixel and cause display malfunction in the display panel.

The structure of the display panel according to at least one embodiment of the present application is described in detail below in connection with the accompanying drawings. Furthermore, in these accompanying drawings, a space rectangular coordinate system is established based on a base (or a display base) in the display panel, so as to visualize the positional relationship of the various elements in the display panel. In the pace rectangular coordinate system, the X-axis and the Y-axis are parallel to the plane where the base is located, and the Z-axis is perpendicular to the plane where the substrate is located.

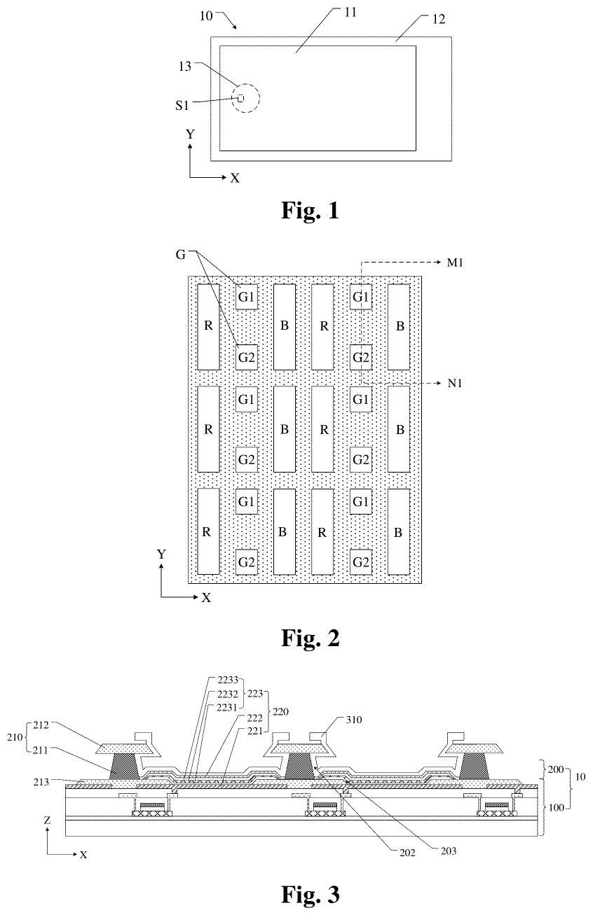

As shown in FIGS. 1 to 3, the display base 10 in the display panel includes a display area 11 and a frame area 12 surrounding the display area 11, and sub-pixels emitting lights of different colors (which may be referred to as sub-pixels), such as R, G, and B, are distributed in the display area 11. For example, every three neighboring sub-pixels R, G, and B constitutes a pixel (which may be referred to as a large pixel), at least one of the sub-pixels (sub-pixel G in the figures) includes at least two sub-pixel blocks that are spaced apart from each other (e.g., sub-pixel blocks G1, G2), and in such case, even if the sub-pixel block G1 cannot emit light due to the intruded debris, the sub-pixel block G2 can ensure that the sub-pixel G emits a certain amount of light. The first direction may be a direction parallel to the X-axis or the Y-axis.

It should be noted that in the embodiments of the present application, the sub-pixels including a plurality of sub-pixel blocks are all referred to as first sub-pixels, and if all the sub-pixels in the display panel are designed to include sub-pixel blocks, then the display panel includes only the first sub-pixels, in which case the first sub-pixels may emit lights of a plurality of colors; and if a portion of the sub-pixels in the display panel are designed to include sub-pixel blocks, then this portion of the sub-pixels are referred to as the first sub-pixels, while the other portion of the sub-pixels may be categorized as other types of sub-pixels such as second sub-pixels, in which case the first sub-pixels may be designed to emit lights of the same color or a plurality of colors.

For example, in some embodiments of the present application, a design related to brightness compensation may be implemented in the display panel, e.g., taking the sub-pixel G shown in FIG. 2 as the first sub-pixel, under a condition that the sub-pixel block G1 cannot emit light due to the intruded debris, the brightness of the light emitted by the sub-pixel block G2 may be adjusted in accordance with the brightness of the light emitted by the sub-pixel G, so as to adjust the brightness of the sub-pixel G to the expected brightness.

For example, in the second direction, the physical structure of the display base 10 includes a base 100, and a display function layer 200 and an isolation structure 210 located on the base 100. The second direction may be a direction parallel to the Z axis.

For example, the isolation structure 210 defines a plurality of isolation openings 202, in which light-emitting devices 220 are disposed.

The display function layer 200 includes a plurality of light-emitting devices 220, and each sub-pixel block is provided with at least one light-emitting device 220, i.e., the light-emitting device 220 constitutes the physical structure of the sub-pixel and sub-pixel block. The light-emitting device 220 includes a first electrode 221, a light-emitting function layer 223, and a second electrode 222 sequentially stacked on the base 100, and the first electrodes 221 corresponding to the sub-pixel blocks G1, G2 located in the same sub-pixel G are electrically connected to each other directly or indirectly.

It should be noted that the sub-pixel with no sub-pixel block may also include the light-emitting device 220 with the above structure.

For example, the light-emitting function layer 223 may include a first common layer 2231, a light-emitting layer 2232, and a second common layer 2233 sequentially stacked on an anode. The first common layer 2231 may include a hole injection layer, a hole transport layer, an electron blocking layer, and the like. The second common layer 2233 may include an electron injection layer, an electron transport layer, a hole blocking layer, and the like. The arrangement of the isolation structure 210 requires that the first common layers (the main film layer causing current crosstalk) of the various light-emitting devices 220 are electrically disconnected from each other.

In at least one embodiment of the present application, the display area 11 includes a first display area 13, and the isolation structure 210 may define a plurality of light-transmitting openings 201 located in the first display area 13, such that the first display area 13 of the display panel may be light-transmitting.

In the above solutions, the first electrodes 221 of two light-emitting devices 220 in the same first sub-pixel are electrically connected to each other (directly or indirectly), so that the driving manner for the entirety of the pixels is not changed; and the application of the isolation structure 210 may result in that the manufacturing process of the light-emitting device 220 requires no mask plate, and thus it is not necessary to consider the alignment accuracy of the manufacturing process, which is beneficial to reducing the gap size of the light-emitting device 220 so as to increase the pixel arrangement density PPI of the display panel (reference may be made to the description in the following embodiments related to the manufacturing method of the display panel for details); and furthermore, in the first display area 13, by arranging the light-transmitting openings 201 in the isolation structure 210, the area of the display panel in which the light-transmitting openings 201 are arranged can be light-transmitting, so that the first display area 13 of the display panel can achieve transparent display or under-screen recognition functions such as fingerprint recognition and under-screen photography.

In at least one embodiment of the present application, the isolation structure 210 includes a support portion 211 and a crown portion 212 sequentially stacked on the base 100, an orthographic projection of the support portion 211 on the base 100 is located within an orthographic projection of the crown portion 212 on the base 100, the support portion 211 includes a conductive structure, and the second electrode 222 of the light-emitting device 220 is located in the corresponding isolation opening 202 and connected to the support portion 211. In this manner, at the gap between adjacent light-emitting devices 220, the isolation structure 210 is generally presented as wide on the top and narrow on the bottom, and thus during the manufacturing of the light-emitting device 220, the isolation effect of the isolation structure 210 on the light-emitting function layer 223 (the first common layer 2231 included therein is the main film layer causing current crosstalk) can be enhanced, so as to reduce the current crosstalk between adjacent light-emitting devices 220.

It should be noted that in some designs of the present application, the support portion 211 and the crown portion 212 may be designed as a multi-layered stacked structure as shown in FIG. 5, which facilitates the use of different materials for manufacturing, and for example, the support portion 211 in the following embodiments is designed to be conductive, while the crown portion 212 is not limited to being designed to be conductive; alternatively, in other designs of the present application, the support portion 211 and the crown portion 212 may be arranged as an integrated structure to increase the robustness of the isolation structure 210.

In at least one embodiment of the present application, as shown in FIG. 5, the support portion 211 may include a conductive structure, and the second electrode 222 is located in the isolation opening 202 and connected to the support portion 211. In this way, the support portions 211 of the isolation structure 210 connect the second electrodes 222 in series, such that the support portions 211 and the second electrodes 222 form a common electrode to facilitate driving.

It should be noted that the material of the second electrode 222 may be a metal material, and the smaller the thickness of the second electrode 222, the greater its light transmittance, but also the higher its resistivity, and if the thickness of the second electrode 222 is too small, under a condition the isolation structure 210 is not arranged, the voltage drop of the second electrode 222 (which is the common electrode in such case) may be too great. In the embodiments of the present application, the second electrode 222 is connected to the support portion 211 which is conductive, and thus the limit on the thickness of the second electrode 222 can be released, so that the second electrode 222 can have a smaller thickness to achieve a greater light transmittance.

In at least one embodiment of the present application, the support portion 211 may include a metal conductive structure, and with the high electric conductivity of the metal material, the voltage drop when the cathode is driven can be reduced. Accordingly, the metal material may be light-transmitting only when its thickness is extremely small (e.g., tens of nanometers), while the isolation structure 210 needs a certain thickness for isolating the light-emitting function layer 223 (the first common layer 2231 included therein), and accordingly, the support portion 211 in the isolation structure 210 is almost lighttight, and thus the isolation structure 210 may be light-transmitting only by arranging the light-transmitting openings 201.

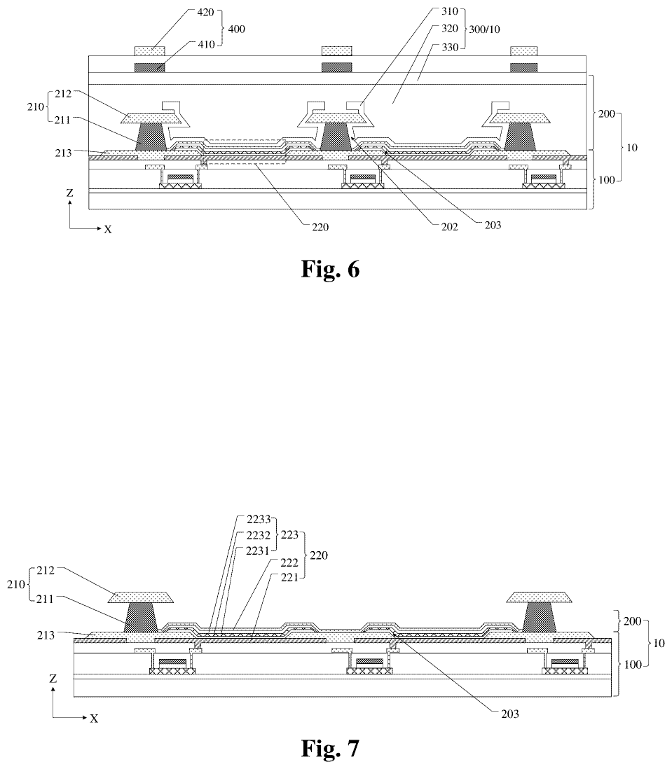

In at least one embodiment of the present application, as shown in FIGS. 5 and 6, the display base may further include a pixel defining layer 213 located at a side of the isolation structure 210 close to the base 100, i.e., the pixel defining layer 213 is located between the base 100 and the isolation structure 210, and the pixel defining layer 213 includes a plurality of pixel openings 203 respectively corresponding to the isolation openings 202. The pixel opening 203 accommodates the light-emitting device 220 and exposes the first electrode 221, the pixel openings 203 are respectively corresponding to the isolation openings 202, and the pixel opening 203 is communicated to the corresponding isolation opening 202.

The light-emitting device 220 is less bright when activated at a lower voltage, which results in poor visual effect, and in the presence of leakage currents, the light-emitting device 220 may emit light even at a low gray scale (e.g., a dark state), i.e., it cannot be turned off.

As shown in FIG. 7, in at least one embodiment of the present application, in the first sub-pixel, an orthographic projection of the pixel openings 203 corresponding to at least two sub-pixel blocks on the base 100 is located within an orthographic projection of a same isolation opening 202 on the base 100. The pixel opening 203 corresponding to the sub-pixel block is the pixel opening 203 in which the light-emitting device 220 of the sub-pixel block is located, and the first sub-pixel as a whole is partitioned by the isolation structure 210, so that the light-emitting function layers 223 of the various sub-pixel blocks in the first sub-pixel are located within the same isolation opening 202, i.e., it is not necessary to arrange the isolation structure 210 between the various sub-pixel blocks of the first sub-pixel, while the sub-pixel blocks of the first sub-pixel are spaced apart from each other only by the pixel defining layer 213, and thus the overall difficulty for manufacturing the isolation structure 210 is reduced. Moreover, the sub-pixel blocks in the same first sub-pixel emit lights of the same color, and thus color mixing problem caused by carrier crosstalk will not occur among the light-emitting function layers 223 of the various sub-pixel blocks. Therefore, even if the isolation structure 210 is not arranged between the sub-pixel blocks of the same first sub-pixel, the light-emitting effect of the first sub-pixel can still be ensured.

As shown in FIG. 3, in at least one embodiment of the present application, an orthographic projection of the pixel opening 203 corresponding to each the sub-pixel block on the base 100 is located within an orthographic projection of the isolation opening 202 on the base 100. The sub-pixel blocks are all separated by the isolation structure 210, i.e., the sub-pixel blocks are separated directly by the isolation structure 210, and thus no other mask plate is required for manufacturing the sub-pixel blocks, and the cost is reduced. Moreover, the isolation structure 210 provides good separating effect, so that the light-emitting function layers 223 of the various sub-pixel blocks are insulated from each other and do not affect each other. The first sub-pixel is divided into a plurality of independent sub-pixel blocks, so that when at least one of the sub-pixel blocks is damaged and causes dark spot, the other sub-pixel blocks continue to emit light normally, so as to ensure that the display panel emits light normally. That is, the division of the first sub-pixel into a plurality of sub-pixel blocks can reduce the effect of single dark spot on the display of the display panel.

In at least one embodiment of the present application, as shown in FIGS. 5 and 6, an orthographic projection of a gap between two adjacent first electrodes 221 on the base 100 is located within an orthographic projection of the support portion 211 on the base 100 to overlap the edges of the first electrodes 221 with the edges of the support portion 211 to form a capacitor, and the pixel defining layer 213 covers the edges of the first electrodes 221 to separate the support portion 211 and the first electrodes 221. In this way, with the capacitor formed by the edge portions of the support portion 211 and the first electrodes 221, the light-emitting device 220 can be charged in the activating phase to increase the activating voltage of the light-emitting device 220, so as to enable the light-emitting device 220 to satisfy the preset brightness requirement when emitting light. In addition, this design can further prevent the light-emitting device 220 from emitting light at a low gray scale.

Optionally, for example, the pixel defining layer 213 is an inorganic layer. The thickness of the inorganic layer is small, so as to ensure that the capacitor that can be formed between the edges of the first electrodes 221 and the edges of the support portion 211 has sufficient electric capacity. In at least one embodiment of the present application, the isolation structure 210 extends continuously between two adjacent sub-pixel blocks to block the light between the two adjacent sub-pixel blocks by the isolation structure 210. With the isolation structure 210 extending continuously between adjacent sub-pixel blocks, the light between two adjacent sub-pixel blocks is blocked by the isolation structure 210, it is avoided that stray light passes through the area between the adjacent sub-pixel blocks to reach the light-emitting surface of the display panel and affect the display of the display panel. Moreover, the isolation structure 210 extends continuously to increase the distribution area of the isolation structure 210, and the isolation structure 210 may include a metal material or other material with reflective effect, and thus the isolation structure 210 with a large area can increase the amount of the reflected light and further increase the brightness of the display panel.

In addition, the display panel may have touch control function as well as functions such as transparent display and under-screen recognition (fingerprint recognition, under-screen photography). In such case, a light-transmitting area is partitioned in the display panel, and light-transmitting holes are arranged at the gaps among the sub-pixels in the light-transmitting area to achieve light transmission. However, in the area where the light-transmitting holes are located, signal interference may occur between the conductive structure (e.g., the touch control electrode as described below) for achieving the touch control function and an underlying driving circuit (e.g., the pixel driving circuit in the base as described below), resulting in poor touch control or display function.

For example, as shown in FIGS. 1 and 4 to 9B, a light-transmitting opening 201 is arranged in the first display area 13, and the sub-pixel G is the first sub-pixel and separated into two sub-pixel blocks G1, G2 by the light-transmitting opening 201. In this way, the light-transmitting opening 201 is arranged so that the first display area 13 has a certain light transmittance for under-screen recognition/photography or transparent display. It should be noted that in some embodiments of the present application, some of the wirings in the frame area 12 may be distributed into the display area 11, so that the frame area 12 may be designed as a single side frame.

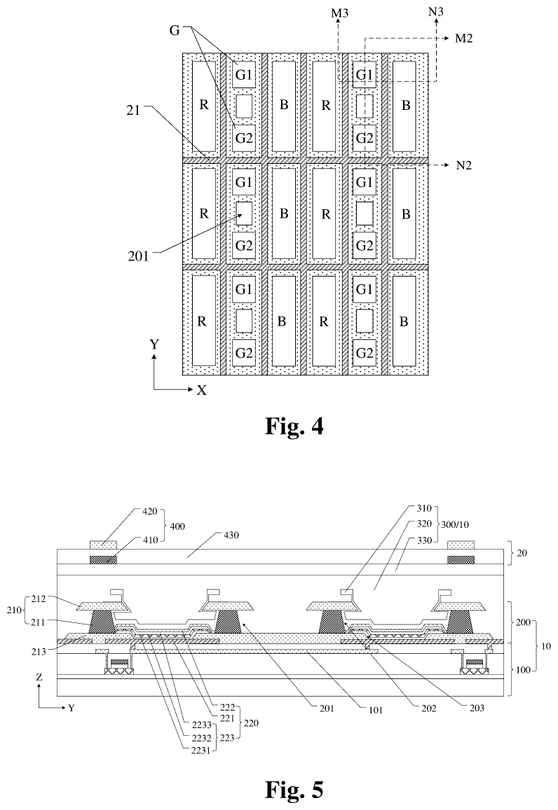

For example, as shown in FIGS. 1 and 4 to 9B, the display panel may further include a touch control structure 20 located at the light-emitting side of the display base 10 and including a plurality of touch control electrodes 400 formed as a mesh, and orthographic projections of the mesh lines of the mesh of the touch control electrode 400 on the base 100 are located in the gaps among the sub-pixels (the sub-pixels here may all or partially be the first sub-pixels). In this way, in the area where the light-transmitting opening 201 is located, the mesh lines 21 of the touch control electrode 400 surround the periphery of the light-transmitting opening 201, i.e., at least one side of the light-transmitting opening 201 (three sides in FIG. 4) is separated from the mesh lines 21 by sub-pixels or sub-pixel blocks (e.g., sub-pixel blocks G1, G2). Therefore, at the light-transmitting opening 201, the distances between the mesh lines 21 of the touch control electrode 400 and the driving circuit in the display base 10 are increased, thereby reducing the interference between the touch control electrode 400 and the driving circuit.

In the embodiments of the present application, the specific structure of the touch control electrode is not limited and may be designed according to actual process requirements. Different designs for the touch control electrode are illustrated below through different embodiments.

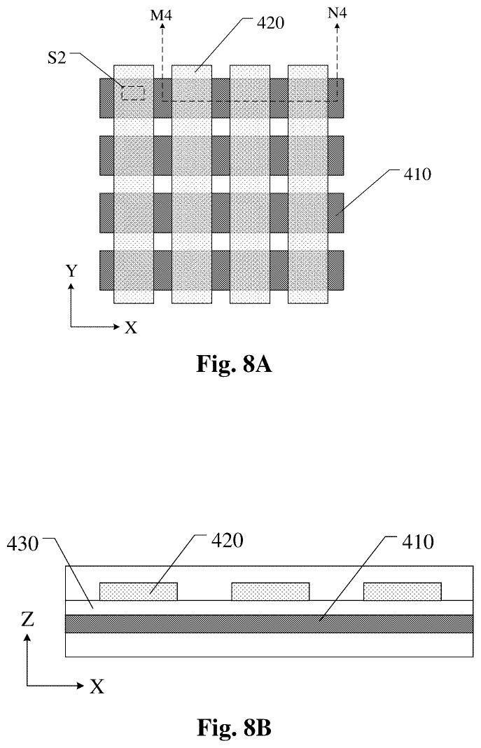

In at least one embodiment of the present application, as shown in FIGS. 8A and 8B, the touch control electrode 400 includes a plurality of first electrode strips 410 that are parallel and a plurality of second electrode strips 420 that are parallel, the first electrode strip 410 and the second electrode strip 420 are spaced apart from each other and intersect with each other to form a touch control unit at the intersection, and the first electrode strips 410 and the second electrode strips 420 are arranged as a mesh-like electrode.

For example, in some embodiments of the present application, as shown in FIGS. 8A and 8B, the first electrode strip 410 is located between the second electrode strip 420 and the isolation structure 210. Generally, the area where the first electrode strip 410 and the second electrode strip 420 intersect and overlap is the area where the touch control unit is located, and in this overlapping area, both the first electrode strip 410 and the second electrode strip 420 are transparent. The first electrode strip 410 and the second electrode strip 420 may be separated by an insulating layer 430.

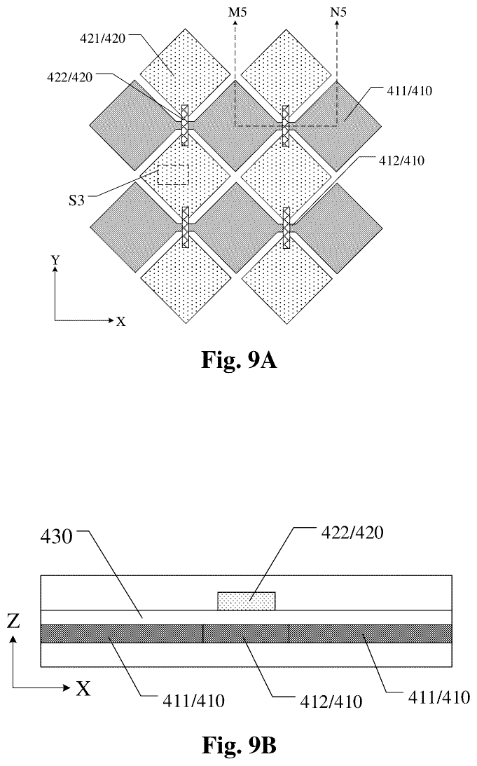

For example, in some other embodiments of the present application, as shown in FIGS. 9A and 9B, the first electrode strip 410 includes a plurality of first electrode blocks 411 that are spaced apart and a plurality of first connecting portions 412, and the plurality of first electrode blocks 411 of the same first electrode strip 410 are connected by the first connecting portions 412. The second electrode strip 420 includes a plurality of second electrode blocks 421 and a plurality of second connecting portions 422, and the plurality of second electrode blocks 421 of the same second electrode strip 420 are connected by the second connecting portions 422. The first connecting portion 412 and the second connecting portion 422 intersect and are spaced apart from each other, in which the first electrode block 411, the first connecting portion 412, and the second electrode strip 420 are arranged in the same layer, and the second connecting portion 422 is located between the first connecting portion 412 and the isolation structure 210, or the second connecting portion 422 is located at a side of the first connecting portion 412 away from the isolation structure 210. The touch control electrode 400 in this design has a great light transmittance, and the alignment accuracy between the mesh hole and the light-transmitting opening 201/the isolation opening 202 is high, so that the light transmittance of the first display area 13 can be increased. In this design, the main bodies of the first electrode strip 410 and the second electrode strip 420 are arranged in the same layer, and thus it is not necessary to consider the mesh hole alignment for the first electrode strip 410 and the second electrode strip 420, which is beneficial to increasing the light transmittance of the touch control electrode 400. For example, the second connecting portion 422 and the first connecting portion 412 may be separated by the insulating layer 430.

In the embodiments of the present application, the type and number of the sub-pixels provided with sub-pixel blocks are not limited and may be selected according to actual process requirements. Different cases are illustrated below based on different embodiments.

For example, reference may be made to FIG. 4 again, the sub-pixels included in each pixel are categorized as first sub-pixels R, second sub-pixels G, and third sub-pixels B, which emit lights of different colors, and the second sub-pixels G are located between the first sub-pixels R. It should be noted that the number of the color of emitted light of the sub-pixels included in each pixel may be designed according to actual process requirements and are not limited in the embodiments of the present application. For example, the first sub-pixel may emit light of at least one color elected from red, green, or blue.

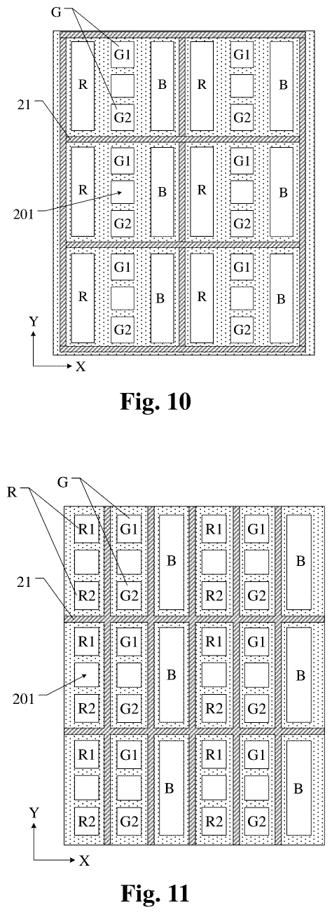

In some embodiments of the present application, in each pixel, the sub-pixel located at the middle position is designed to include sub-pixel blocks, i.e., the first sub-pixel is a first-color sub-pixel emitting light of one color. The first display area further includes a plurality of second-color sub-pixels and a plurality of third-color sub-pixels that are arranged in an array in the first direction, in which every adjacent first-color sub-pixel, second-color sub-pixel, and third-color sub-pixel constitute a pixel. In each pixel, the first-color sub-pixel is located between the second-color sub-pixel and the third-color sub-pixel, the first-color sub-pixel, the second-color sub-pixel, and the third-color sub-pixel emit lights of different colors, and the second-color sub-pixel and the third-color sub-pixel each include a continuous structure. Optionally, for example, along a direction from the second-color sub-pixel to the third-color sub-pixel, the width of the first-color sub-pixel is equal to the width of the light-transmitting opening. Optionally, for example, the wavelengths of the lights emitted by the second-color sub-pixel, the first-color sub-pixel, and the third-color sub-pixel decrease successively. For example, as shown in FIGS. 4 and 10, the second-color sub-pixel, the first-color sub-pixel, and the third-color sub-pixel are sub-pixel R, sub-pixel G, and sub-pixel B, respectively, the sub-pixel G is designed to include at least two sub-pixel blocks G1, G2 separated by the light-transmitting opening 201, and the sub-pixel R and the sub-pixel B each include a continuous structure.

Under a condition the sub-pixel G is designed to include sub-pixel blocks, the width of the light-transmitting opening 201 corresponding to the sub-pixel G may be designed according to whether the mesh lines 21 are arranged around. For example, as shown in FIG. 4, under a condition that the sub-pixel G is arranged with the mesh lines 21, along a direction from the sub-pixel R to the sub-pixel B (the direction of the X-axis in FIG. 4), the width of the sub-pixel G is greater than the width of the light-transmitting opening 201. Alternatively, as shown in FIG. 10, the light-transmitting opening 201 is spaced apart from the mesh lines 21 by the sub-pixel blocks G1, G2, the sub-pixel R, and the sub-pixel B, and thus the light-transmitting opening 201 is not adjacent to the mesh lines 21, and along the direction from the sub-pixel R to the sub-pixel B, the width of sub-pixel G is equal to the width of the light-transmitting opening 201, so that the light-transmitting opening 201 may have a large design area to increase the light transmittance of the first display area. Furthermore, the spacing between the light-transmitting opening 201 and the mesh lines 21 is large, and thus the mutual interference between the touch control function and the display function when they are driven can be significantly reduced.

In embodiments of the present application, the “continuous structure” means that all portions in the planar pattern of the target object are connected together, and there is only one outer edge with no inner edge, i.e., the continuous structure does not enclose any opening.

In some other embodiments of the present application, in each pixel, at least two adjacent sub-pixels may be designed to include sub-pixel blocks, and at least one sub-pixel is designed to include a continuous structure, i.e., the first sub-pixel is categorized as at least a first-color sub-pixel and a second-color sub-pixel that emit lights of two colors, respectively. The first display area further includes a plurality of third-color sub-pixels arranged in an array in the first direction, in which every adjacent first-color sub-pixel, second-color sub-pixel, and third-color sub-pixel constitute a pixel. In each pixel, the second-color sub-pixel is located between the first-color sub-pixel and the third-color sub-pixel, and the third-color sub-pixel includes a continuous structure. Optionally, for example, in each pixel, the light-transmitting openings corresponding to the first-color sub-pixel and the second-color sub-pixel are communicated to each other. Optionally, for example, at a side of the first-color sub-pixel away from the second-color sub-pixel, a distance from the light-transmitting opening to the mesh line is greater than a distance from the first-color sub-pixel to the mesh line. Optionally, for example, the wavelengths of the lights emitted by the first-color sub-pixel, the second-color sub-pixel, and the third-color sub-pixel decrease successively. For example, as shown in FIGS. 11 to 13, the first-color sub-pixel, the second-color sub-pixel, and the third-color sub-pixel are sub-pixel R, sub-pixel G, and sub-pixel B, respectively, the sub-pixel R is designed to include at least two sub-pixel blocks R1, R2 separated by the light-transmitting opening 201, the sub-pixel G is designed to include at least two sub-pixel blocks G1, G2 separated by the light-transmitting opening 201, and the sub-pixel B includes a continuous structure.

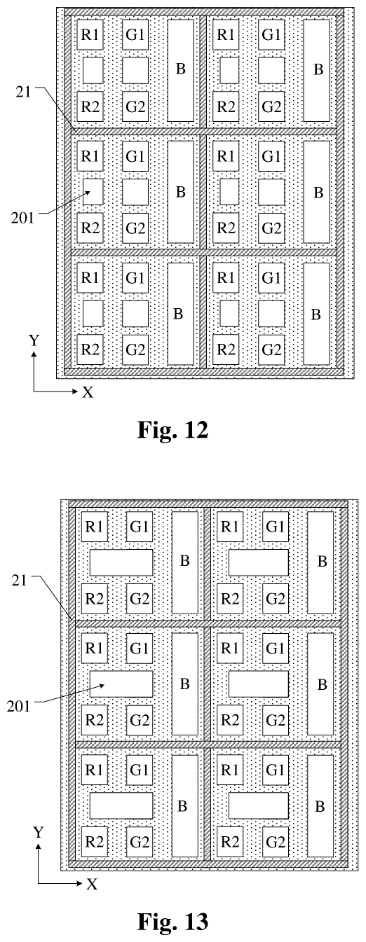

For example, under a condition that both the sub-pixel R and the sub-pixel G are designed to include two sub-pixel blocks, as shown in FIG. 12, the side edge of the light-transmitting opening 201 adjacent to the mesh line 21 may be shifted inwardly to increase the spacing between the light-transmitting opening 201 and the mesh line 21, i.e., at a side of the sub-pixel R away from the sub-pixel G, a distance from the light-transmitting opening 201 to the mesh line 21 is greater than a distance from the sub-pixel R to the mesh line 21.

For example, under a condition that both the sub-pixel R and the sub-pixel G are designed to include two sub-pixel blocks, adjacent light-transmitting openings may be combined to increase the design area of the opening for light transmission. As shown in FIG. 12, in each pixel, the light-transmitting openings 201 corresponding to the sub-pixel R and the sub-pixel G are communicated to each other. In this way, the light-transmitting opening 201 can have a larger design area (the number of the light-transmitting openings 201 increases), so that the first display area 13 has a greater light transmittance.

In yet some other embodiments of the present application, in each pixel, all the sub-pixels may be designed to include sub-pixel blocks, i.e., the first sub-pixel is categorized as at least a first-color sub-pixel, a second-color sub-pixel, and a third-color sub-pixel that emit lights of three colors, respectively. Every adjacent first-color sub-pixel, second-color sub-pixel, and third-color sub-pixel constitute a pixel, and in each pixel, the second-color sub-pixel is located between the first-color sub-pixel and the third-color sub-pixel. Optionally, for example, in each pixel, the light-transmitting openings corresponding to the first-color sub-pixel, the second-color sub-pixel, and the third-color sub-pixel are communicated to each other. Optionally, for example, at a side of the first-color sub-pixel away from the second-color sub-pixel, a distance from the light-transmitting opening to the mesh line is greater than a distance from the first-color sub-pixel to the mesh line, and at a side of the third-color sub-pixel away from the second-color sub-pixel, a distance from the light-transmitting opening to the mesh line is greater than a distance from the third-color sub-pixel to the mesh line. Optionally, for example, the wavelengths of the lights emitted by the first-color sub-pixel, the second-color sub-pixel, and the third-color sub-pixel decrease successively. Optionally, for example, the first-color sub-pixel, the second-color sub-pixel, and the third-color sub-pixel emit red light, green light, and blue light, respectively. For example, as shown in FIG. 14, the first-color sub-pixel, the second-color sub-pixel, and the third-color sub-pixel are sub-pixel R, sub-pixel G, and sub-pixel B, respectively, and the sub-pixel R, the sub-pixel G, and the sub-pixel B are all designed to include at least two sub-pixel blocks separated by the light-transmitting opening 201. For example, in each pixel, the light-transmitting openings 201 corresponding to the sub-pixel R, the sub-pixel G, and the sub-pixel B are communicated to each other. For example, further, at a side of the sub-pixel R away from the sub-pixel G, a distance from the light-transmitting opening 201 to the mesh line 21 is greater than a distance from the sub-pixel R to the mesh line 21, and at a side of the sub-pixel B away from the sub-pixel G, a distance from the light-transmitting opening 201 to the mesh line 21 is greater than a distance from the sub-pixel B to the mesh line 21. In this way, the light-transmitting opening 201 can have a larger design area (the number of the light-transmitting openings 201 increases), so that the first display area 13 has a greater light transmittance; furthermore, in this design, the light-transmitting opening 201 is adjacent to the mesh line 21 with a small length and a large spacing, and thus the mutual interference between the touch function and the display function when they are driven can be reduced.

For example, in at least one embodiment of the present application, the wavelengths of the lights emitted by the sub-pixel R, the sub-pixel G, and the sub-pixel B decrease successively. In this way, the sub-pixel G may be designed to emit light that is more sensitive to human eye, in which case the design area required for the sub-pixel G is relatively small, and under a condition that the sub-pixel G is designed to include sub-pixel blocks, the light emitting efficiency of the pixel is less affected. Further optionally, for example, the sub-pixel R, the sub-pixel G, and the sub-pixel B may be designed to emit red light, green light, and blue light, respectively.

In the embodiments of the present application, under a condition that the mesh lines of the touch control electrode are located in the gaps among the sub-pixels, the specific positional relationship between the mesh line and the sub-pixel is not further limited and may be designed according to actual process requirements. Exemplary illustration is provided below in connection with several specific embodiments.

For example, in some embodiments of the present application, reference may be made to FIGS. 4 and 11 again, the touch control electrode includes a plurality of mesh holes enclosed by the mesh lines 21 and corresponding to the sub-pixels R, G, B in one-to-one correspondence, and the sub-pixel R, G, B is located within the orthographic projection of the corresponding mesh hole on the display base, i.e., the mesh lines encircle each of the sub-pixels R, G, B.

For example, as shown in FIGS. 4 and 11, the centroid of the orthographic projection of the mesh hole on the display base coincides with the centroid of the corresponding sub-pixel R, G, B. This design can reduce brightness difference of the lights emitted by the sub-pixels R, G, B at the same viewing angle and in different directions, so as to mitigate color deviation.

For example, in some other embodiments of the present application, reference may be made to FIGS. 10, and 12 to 14 again, the touch control electrode includes a plurality of mesh holes enclosed by the mesh lines 21 and corresponding to the pixels in one-to-one correspondence, and the pixel is located within the orthographic projection of the corresponding mesh hole on the display base, i.e., the mesh lines 21 encircle the pixels.

For example, as shown in FIGS. 10, and 12 to 14, the centroid of the orthographic projection of the mesh hole on the display base coincides with the centroid of the corresponding pixel. This design can reduce brightness difference of the lights emitted by the sub-pixels at the same viewing angle and in different directions, so as to mitigate color deviation.

In embodiments of the present application, for the first sub-pixel provided with sub-pixel blocks, the manner for connecting the first electrodes of adjacent light-emitting devices is not limited.

For example, in at least one embodiment of the present application, reference may be made to FIG. 5 again, the base plate 100 may include a substrate and a driving circuit layer on the substrate and including a plurality of pixel driving circuits located in the display area, and the display function layer is located on the driving circuit layer. For example, the pixel driving circuit may include a plurality of transistors TFTs, capacitors, etc., and formed, for example, in a variety of forms such as 2T1C (i.e., 2 transistors (TFTs) and 1 capacitor (C)), 3T1C, or 7T1C. The pixel driving circuit is connected to the light-emitting device 220 to control the on/off state and brightness of the light-emitting device 220.

In some embodiments of the present application, reference may be made to FIG. 5 again, an orthographic projection of the first electrode 221 on the base 100 is located outside an orthographic projection of the light-transmitting opening 201 on the base 100, a wire 101 is arranged in the base 100, and in the first sub-pixel with sub-pixel blocks, the first electrodes 221 of the light-emitting devices 220 corresponding to two adjacent sub-pixel blocks are connected to each other via the wire 101. In this design, the first electrode 221 is arranged away from the light-transmitting opening 201, so that the light transmittance of the display panel at the light-transmitting opening 201 can be increased, thereby increasing the light transmittance of the first display area 13. The wire 101 has a small width and is more easily to be arranged away from the light-transmitting opening 201, so as not to affect the light transmittance at the light-transmitting opening 201.

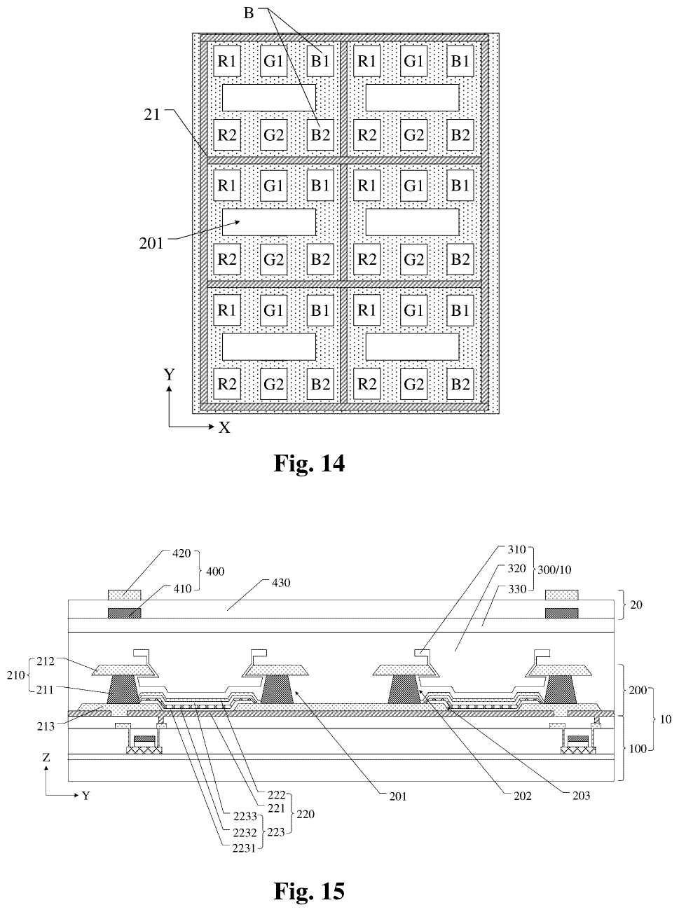

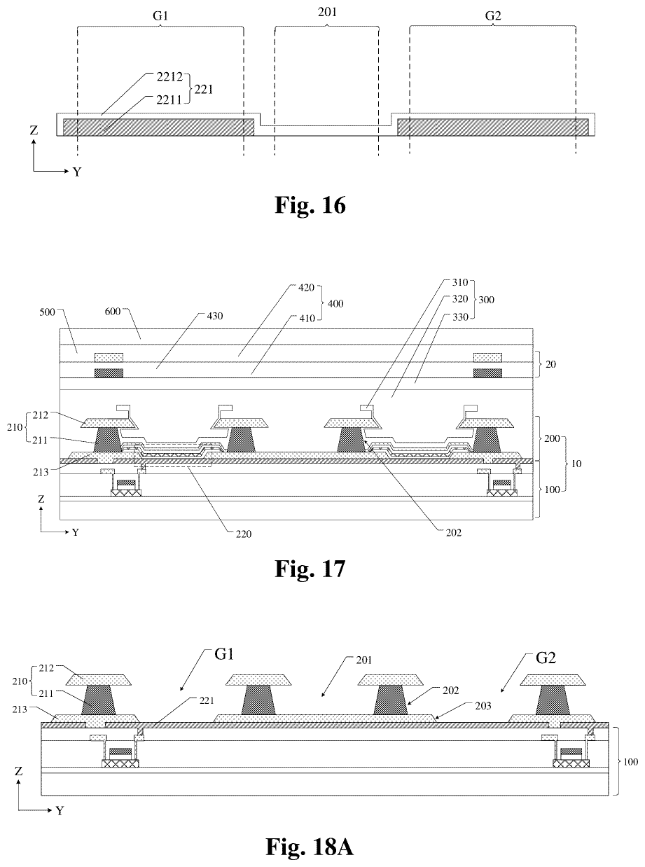

In some other embodiments of the present application, as shown in FIGS. 15 and 16, the first electrode 221 includes a reflective electrode layer 2211 and a transparent electrode layer 2212 stacked on the base 100, and the reflective electrode layer 2211 is located between the base 100 and the transparent electrode layer 2212. In the first sub-pixel with sub-pixel blocks, the first electrodes 221 of the light-emitting devices 220 in the sub-pixel blocks are connected via the transparent electrode layer 2212, and the orthographic projection of the light-transmitting opening 201 on the base 100 is located within an orthographic projection of the transparent electrode layer 2212 on the base 100. This design enables that the arrangement of the isolation opening 202 will not increase the difficulty of the manufacturing process of the display base and will not affect the distribution of the circuits in the base 100.

For example, the first electrode 221 may be an anode, and the second electrode 222 may be a cathode. The main material of the anode is high work function material, which may be ITO, IGO, etc., with great light transmittance. In practice, the light-emitting device 220 is designed with a top-emitting mode, and thus a reflective layer may be arranged in the anode so that the light excited by the light-emitting function layer 223 is reflected to a side away from the anode. In order to ensure the electric conductivity of the anode, a highly reflective and conductive material such as metal is used for the reflective layer.

In some other embodiments of the present application, the first electrode 221 as shown in FIGS. 15 and 16 may be modified such that in the first sub-pixel, the light-emitting devices 220 corresponding to two adjacent sub-pixel blocks share the first electrode 221. For example, at the location where the light-transmitting opening 201 is located, the first electrode 221 may be provided with a via overlapping the light-transmitting opening 201 to avoid blocking the light emitted into the light-transmitting opening 201. In such case, the orthographic projection of the light-transmitting opening 201 on the base may overlap an orthographic projection of the via of the first electrode 221 on the base, or the orthographic projection of the light-transmitting opening 201 on the base may be located within the orthographic projection of the via of the first electrode 221 on the base.

In at least one embodiment of the present application, as shown in FIG. 17, the display panel may further include a first encapsulation layer 310 that covers at least the light-emitting device 220 to protect the film layers of the light-emitting device 220 during the manufacturing process of the display panel. It should be noted that the light-emitting devices 220 emitting lights of different colors are independently manufactured, but the film layer (an evaporated film layer such as the light-emitting function layer 223) in each of the light-emitting devices 220 is evaporated, as a whole, on the display panel during evaporation. For example, the light-emitting devices 220 are categorized as light-emitting devices that emit red light (R), green light (G), and blue light (B), respectively, and in the manufacturing process, the light-emitting devices R, G, B are manufactured sequentially. In manufacturing the light-emitting device R, the light-emitting device R is formed in each of the isolation openings 202, and the first encapsulation layer 310 is manufactured on the display panel to cover the light-emitting device R, and then the first encapsulation layer 310 in a portion of the isolation openings 202 (for forming the light-emitting devices G, B in the final product) and the cathode and the light-emitting function layer 223 of the light-emitting device R are removed (the remaining portion of the first encapsulation layer 310 is an encapsulation unit covering the light-emitting device). In this process, the first encapsulation layer 310 is used to protect the light-emitting devices R in the other isolation openings, and in this manner, the light-emitting devices G, B are then manufactured sequentially, so as to ultimately form the first encapsulation layer 310 as shown in FIG. 5, and accordingly, the first encapsulation layer 310 is consists of the encapsulation units covering the light-emitting devices 220, respectively. It should be noted that in the above manufacturing process, the first encapsulation layer 310 in the light-transmitting opening 201 may be removed to further increase the light transmittance of the first display area.

In at least one embodiment of the present application, reference may be made to FIG. 5 again, the display panel may further comprise a second encapsulation layer 320 and a third encapsulation layer 330 covering the first encapsulation layer 310, and the second encapsulation layer 320 is located between the first encapsulation layer 310 and the third encapsulation layer 330. The first encapsulation layer 310 and the third encapsulation layer 330 are inorganic layers which are highly dense to insulate from water and oxygen, and the second encapsulation layer 320 is an organic layer and thus has a great thickness to flatten the surface of the display panel.

For example, as shown in FIG. 17, the display panel may further include structures such as an optical film 500 and a cover plate 600, which may be located at a side of the touch control structure way from the display base.

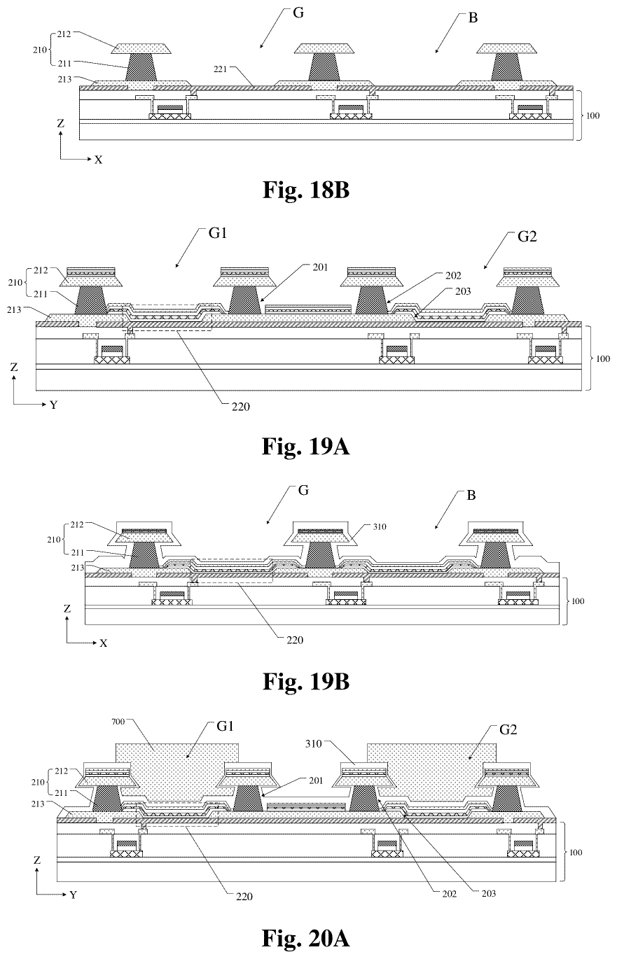

The manufacturing process of the display panel as shown in FIGS. 5 and 6 is described below in connection with FIGS. 18A, 18B, 19A, 19B, 20A, 20B, 21A, 21B, and 22, so as to visualize the principle that the isolation structure can increase the pixel arrangement density PPI, in which FIGS. 18A, 19A, 20A, and 21A correspond to the manufacturing process for the display panel as shown in FIG. 5, and FIGS. 18B, 19B, 20B, 21B, and 22 correspond to the manufacturing process for the display panel as shown in FIG. 6.

As shown in FIGS. 18A and 18B, a base 100 is provided and first electrodes 221 arranged in an array are formed on the base 100; an insulating material film layer (e.g., an inorganic material film layer) is deposited on the base 100 with the first electrodes formed; a support portion 211 and a crown portion 212, in which a light-transmitting opening 201 and an isolation opening 202 are formed, are formed on the display panel; the insulating material film layer is patterned to form a pixel defining layer 213 (with a planar shape in the form a mesh), the pixel defining layer 213 includes a third via and covers gaps between adjacent first electrodes, and thus the pixel defining layer 213 has a planar shape in the form of a mesh.

In embodiments of the present application, the patterning process may be a photolithography patterning process, which may include, for example: coating photoresist on a structure layer to be patterned, exposing the photoresist using a mask plate, developing the exposed photoresist to obtain a photoresist pattern, etching (a wet etch or a dry etch may be selected) the structure layer using the photoresist pattern, and then optionally removing the photoresist pattern. It should be noted that if the material of the structure layer (e.g., the photoresist pattern 700 described below) includes photoresist, the structure layer may be directly exposed through a mask plate to form the desired pattern.

As shown in FIGS. 19A and 19B, a light-emitting function layer and a second electrode are evaporated on the base 100 to form a light-emitting device 220 in each of the light-transmitting openings 201 of the isolation structure 210. The evaporation in this process does not utilize a mask plate, and thus the evaporated material may also be deposited on the crown portion 212, as well as in the light-transmitting opening 201 and the isolation opening 202. For example, the evaporated light-emitting function layer may emit red light (G), i.e., in this phase, the light-emitting device 220 emitting red light is formed in each of the light-transmitting openings 201 and the isolation openings 202 of the isolation structure 210.

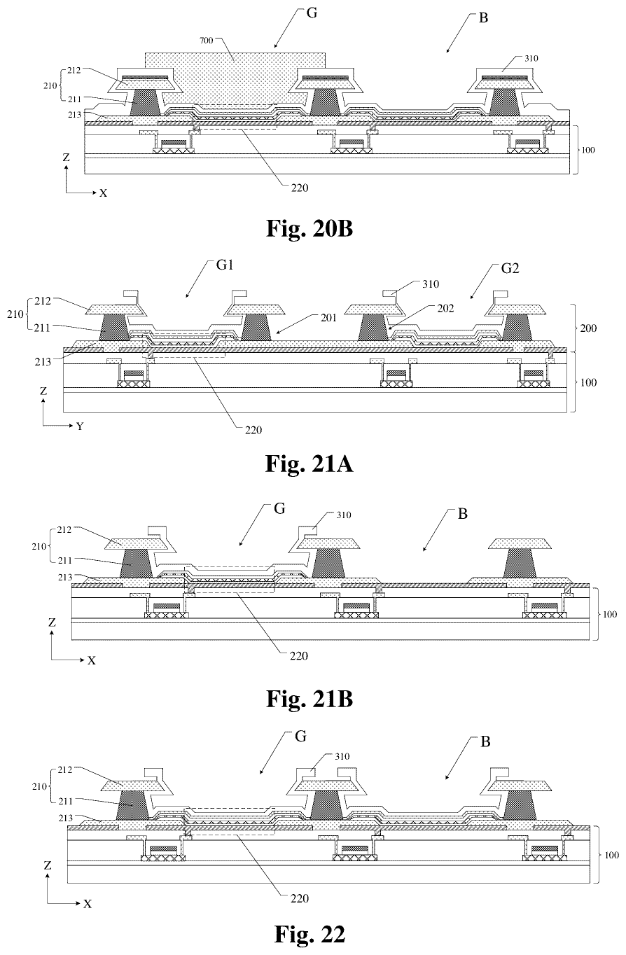

As shown in FIGS. 20A and 20B, a first encapsulation layer 310 is deposited to cover the light-emitting device 220, and the first encapsulation layer 310 may cover the entire display area in this phase; photoresist is formed (e.g., coated) on the first encapsulation layer 310 and then patterned to form a photoresist pattern 700, which covers only a portion of the isolation openings 202 (the isolation openings 202 where the light-emitting devices G of the final display panel are located) of the isolation structure 210.

As shown in FIGS. 21A and 21B, the surface of the display panel is etched using the photoresist pattern 700 as a mask to remove the first encapsulation layer 310, the second electrode, and the light-emitting function layer that are not covered by the photoresist pattern 700; and then the residual photoresist pattern 700 is removed.

As shown in FIG. 22, the above steps are repeated to form light-emitting devices 220 emitting green light and blue light in other isolation openings 202, respectively.

After all the light-emitting devices 220 have been manufactured, a second encapsulation layer 320 and a third encapsulation layer 330 are formed on the first encapsulation layer 310.

Reference may be made to FIGS. 5 and 6 again, a touch control electrode 400 is manufactured on the third encapsulation layer 330.

It should be noted that the order for manufacturing the light-emitting devices 220 emitting red light, green light and blue light may be designed according to actual requirements and is not limited in the embodiments of the present application.

It should be noted that in some embodiments of the present application, a portion of the film layers in the light-emitting function layer, such as the light-emitting layer, may be manufactured using a non-evaporating method, such as inkjet printing, which may be selected according to the material of the film layers. For example, under a condition that the film layers include polymer materials for which evaporation is not applicable, the film layers may be manufactured using inkjet printing.

It should be noted that in the embodiments of the present application, the design area of the first display area is not limited and may be designed according to the actual process requirements and the application scenario of the display panel.

For example, in some embodiments of the present application, the entirety of the display area may be designed as the first display area 13. In this design, the display panel may be used in scenarios such as transparent display.

For example, in some other embodiments of the present application, reference may be made to FIG. 1 again, the display area further includes a second display area (an area within the display area 11 but outside the first display area 13) located at at least one side of the first display area 13, the first display area 13 is a light-transmitting area, while the second display area is a non-light-transmitting area. In this design, the display panel may be used in scenarios such as fingerprint recognition or under-screen photography.

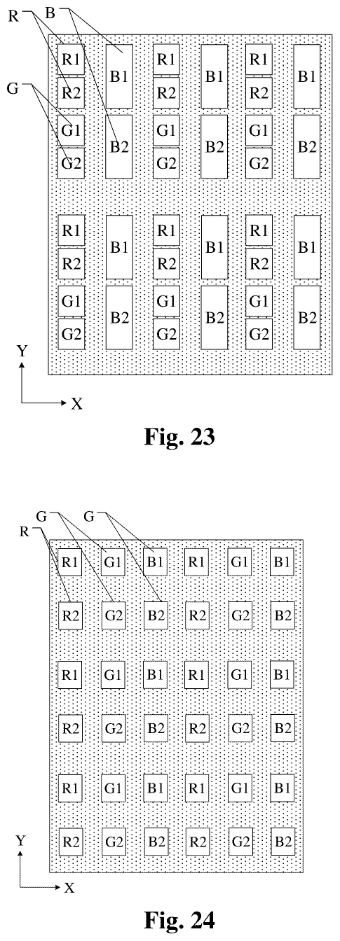

In at least one embodiment of the present application, the first sub-pixel includes a first-color sub-pixel, a second-color sub-pixel, and a third-color sub-pixel that are spaced apart from each other and of different colors, and the first-color sub-pixel, the second-color sub-pixel, and the third-color sub-pixel are arranged adjacently. Optionally, for example, the first-color sub-pixel, the second-color sub-pixel, and the third-color sub-pixel emit red light, green light, and blue light, respectively. For example, the first-color sub-pixel, the second-color sub-pixel, and the third-color sub-pixel are sub-pixel R, sub-pixel G, and sub-pixel B, respectively; or the first-color sub-pixel, the second-color sub-pixel, and the third-color sub-pixel are sub-pixel R, sub-pixel B, and sub-pixel G, respectively; or the first-color sub-pixel, the second-color sub-pixel, and the third-color sub-pixel are sub-pixel G, sub-pixel R, and sub-pixel B, respectively; or the first-color sub-pixel, the second-color sub-pixel, and the third-color sub-pixel are sub-pixel G, sub-pixel B, and sub-pixel R, respectively; or the first-color sub-pixel, the second-color sub-pixel, and the third-color sub-pixel are sub-pixel B, sub-pixel G, and sub-pixel R, respectively; or the first-color sub-pixel, the second-color sub-pixel, and the third-color sub-pixel are sub-pixel B, sub-pixel R, and sub-pixel G, respectively. Herein, for example, the first-color sub-pixel, the second-color sub-pixel, and the third-color sub-pixel are sub-pixel R, sub-pixel G, and sub-pixel B, respectively. As shown in FIG. 23, in at least one embodiment of the present application, the second-color sub-pixel G (e.g., sub-pixel blocks G1, G2) is located at one side of the first-color sub-pixel R (e.g., sub-pixel blocks R1, R2) in a second direction, the third-color sub-pixel B (e.g., sub-pixel blocks B1, B2) is located at one side of the first-color sub-pixel in the first direction, and the first direction is intersected with the second direction. That is, the first-color sub-pixel, the second-color sub-pixel, and the third-color sub-pixel are arranged circularly. Optionally, for example, the first-color sub-pixel and the second-color sub-pixel are located at one side of the third-color sub-pixel in the second direction. Herein, the first direction is parallel to the X-axis and the second direction is parallel to the Y-axis.

In at least one embodiment of the present application, in the first direction, the first-color sub-pixel R and the second-color sub-pixel G are of a same length and have two flush side edges to form a rectangular structure. The first-color sub-pixel and the second-color sub-pixel are of a same length in the first direction, so that the first-color sub-pixel and the second-color sub-pixel have similar light-emitting dimensions in the first direction, and thus the light-emitting effect is good. Moreover, the first-color sub-pixel and the second-color sub-pixel have two flush side edges in the first direction to form a rectangular structure, so that the first-color sub-pixel and the second-color sub-pixel are arranged in order, and thus the display uniformity is improved. The first-color sub-pixel and the second-color sub-pixel form a rectangular structure, i.e., the outer contour of the first-color sub-pixel and the outer contour of the second-color sub-pixel are extended and connected to form a rectangular structure, and thus the arrangement is orderly, so as to further improve the display effect of the display panel.

Optionally, in the first direction, the first-color sub-pixel R, the second-color sub-pixel G, and the third-color sub-pixel B are of a same length, so that the first-color sub-pixel, the second-color sub-pixel, and the third-color sub-pixel have similar light-emitting dimensions in the first direction, so as to further improve the light-emitting effect of the display panel.

Optionally, in the second direction, the first-color sub-pixel R and the second-color sub-pixel G are of a same length, so that the first-color sub-pixel and the second-color sub-pixel have similar light-emitting dimensions in the second direction, so as to further improve the light-emitting effect of the display panel.

As shown in FIG. 24, in at least one embodiment of the present application, the first-color sub-pixel (e.g., sub-pixel blocks R1, R2), the second-color sub-pixel (e.g., sub-pixel blocks G1, G2), and the third-color sub-pixel (e.g., sub-pixel blocks B1, B2) are long strip in shape and sequentially arranged at intervals in the first direction, the arrangement manner is simple, and thus the manufacturing difficulty is reduced to facilitate the manufacturing of the first-color sub-pixel, the second-color sub-pixel, and the third-color sub-pixel. Moreover, this arrangement manner is regular, which can improve the display uniformity of the display panel.

In at least one embodiment of the present application, in a second direction intersecting the first direction, the first-color sub-pixel, the second-color sub-pixel, and the third-color sub-pixel are of a same length and have two flush side edges to form a rectangular structure, so that the first-color sub-pixel, the second-color sub-pixel, and the third-color sub-pixel have similar light-emitting dimensions in the second direction, so as to further improve the display effect of the display panel. The first-color sub-pixel, the second-color sub-pixel, and the third-color sub-pixel form a rectangular structure, i.e., the outer contours of the first-color sub-pixel, the second-color sub-pixel, and the third-color sub-pixel are extended and connected to form a rectangular structure, and thus the arrangement is orderly, so as to further improve the display effect of the display panel.

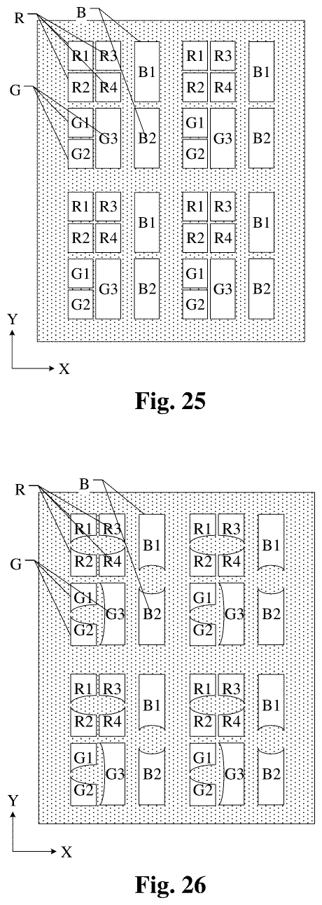

As shown in FIG. 25, in at least one embodiment of the present application, the first sub-pixel includes at least three sub-pixel blocks (e.g., sub-pixel blocks G1, G2, and G3), and a plurality of the sub-pixel blocks are arranged circularly, i.e., the plurality of sub-pixel blocks are staggered and arranged in different directions, and the plurality of sub-pixel blocks surround a center and arranged around the center. Optionally, for example, in the first sub-pixel, for a same sub-pixel block, at least one of the sub-pixel blocks is arranged at each side of the sub-pixel block in the first direction and the second direction.

As shown in FIGS. 22 and 23, in at least one embodiment of the present application, the isolation structure 210 extends along the first direction and the second direction (the gray-filled portion in FIG. 25 may be considered as the isolation structure 210), and the first sub-pixel separates, through the isolation structure 210, the sub-pixel blocks that are adjacent in the first direction and/or the sub-pixel blocks that are adjacent in the second direction. By arranging the isolation structure 210 and forming the isolation openings 202 corresponding to the various sub-pixel blocks, when manufacturing the sub-pixel blocks, the light-emitting function layers 223 of the various sub-pixel blocks can be separated by the isolation structure 210 and deposited into the various isolation openings 202, thereby forming the sub-pixel blocks that are spaced apart from each in the first direction and the second direction. The isolation structure 210 is such arranged that the sub-pixel blocks are well separated and mutual influence among the sub-pixel blocks is reduced, and when one of the sub-pixel blocks suffers from dark spot problem, the other sub-pixel blocks continue to emit light normally, so as to ensure that the display panel emits light normally. That is, the division of the first sub-pixel, through the isolation structure 210, into a plurality of sub-pixel blocks can reduce the effect of single dark spot on the display of the display panel. For example, when the sub-pixel block R1 in FIG. 25 suffers from dark spot problem, the sub-pixel blocks R2, R3, and R4 continue to emit light normally, thereby ensuring that the first-color sub-pixel emits light normally.

As shown in FIGS. 24 and 25, in at least one embodiment of the present application, the first-color sub-pixel includes a sub-pixel blocks, the second-color sub-pixel includes b sub-pixel blocks, the third-color sub-pixel includes c sub-pixel blocks, and a, b, and c satisfy a≥b≥c. As shown in FIG. 24, if the first-color sub-pixel, the second-color sub-pixel, and the third-color sub-pixel are each divided into a plurality of sub-pixel blocks, the first-color sub-pixel, the second-color sub-pixel, and the third-color sub-pixel include the same number of sub-pixel blocks, the number distribution is regular to improve the display uniformity of the display panel, and the arrangement of the isolation structure 210 is relatively regular to reduce the difficulty for manufacturing the isolation structure 210. As shown in FIG. 25, if a is greater than b, i.e., the number of the sub-pixel blocks (e.g., sub-pixel blocks R1, R2, R3, and R4) of the first-color sub-pixel is greater than the number of the sub-pixel blocks (e.g., sub-pixel blocks G1, G2, and G3) of the second-color sub-pixel, and for example, the first-color sub-pixel includes four sub-pixel blocks, the second-color sub-pixel includes three sub-pixel blocks, the third-color sub-pixel includes two sub-pixel blocks; in the first-color sub-pixel, the number of the sub-pixel blocks is greater and the area of an individual sub-pixel block is smaller, and when at least one of the sub-pixel blocks suffers from dark spot problem, the other sub-pixel blocks emit light normally and have a larger light-emitting area, i.e., the first-color sub-pixel has a greater aperture rate, thereby reducing the effect of single dark spot on the display of the display panel. If the manufacturing of the first-color sub-pixel is after the evaporation of the second-color sub-pixel, the first-color sub-pixel is more vulnerable to dark spot problem, and thus the first-color sub-pixel is divided into a greater number of sub-pixel blocks, so as to further reduce the effect of the dark spot problem on the display. That is, the first sub-pixel that is latterly manufactured is divided into a greater number of sub-pixel blocks, so as to balance the influence from dark spots on the first sub-pixels of various colors to ensure the overall display effect of the display panel. The structure and effect of the second-color sub-pixel and the third-color sub-pixel are the same as those of the first-color sub-pixel and the second-color sub-pixel, and will not be repeated herein.

In at least one embodiment of the present application, the first sub-pixel includes two sub-pixel blocks (e.g., sub-pixel blocks B1 and B2 in FIG. 25) arranged at intervals along the first direction, and the first sub-pixel is divided into sub-pixel blocks that are separated to reduce the effect of single dark spot on the overall light emission of the first sub-pixel. Optionally, for example, in the second direction, the two sub-pixel blocks are of a same length and have two flush side edges to form a rectangular structure, so that the two sub-pixel blocks have similar light-emitting dimensions in the second direction to further improve the light-emitting effect of the first sub-pixel. The two sub-pixel blocks form a rectangular structure, i.e., the outer contours of the two sub-pixel blocks are extended and connected to form a rectangular structure, and thus the arrangement is orderly, so as to further improve the light-emitting effect of the first sub-pixel.

In at least one embodiment of the present application, the first sub-pixel comprises a first sub-pixel block, a second sub-pixel block, and a third sub-pixel block, e.g., in FIG. 25, sub-pixel block G1 is the first sub-pixel block, sub-pixel block G2 is the second sub-pixel block, and sub-pixel block G3 is the third sub-pixel block, the first sub-pixel block and the second sub-pixel block are located at one side of the third sub-pixel block in the first direction, and the first sub-pixel block and the second sub-pixel block are arranged at intervals in the second direction. That is, the first sub-pixel includes three sub-pixel blocks, and the first sub-pixel block, the second sub-pixel block, and the third sub-pixel block are staggered and arranged in different directions, and the first sub-pixel block, the second sub-pixel block, and the third sub-pixel block surround a center and arranged around the center.

Optionally, in the first direction, the first sub-pixel block and the second sub-pixel block are of a same length and have two flush side edges to form a rectangular structure, so that the first sub-pixel block and the second sub-pixel block have similar light-emitting dimensions in the first direction to further improve the light-emitting effect of the first sub-pixel. The first sub-pixel block and the second sub-pixel block form a rectangular structure, i.e., the outer contours of the first sub-pixel block and the second sub-pixel block are extended and connected to form a rectangular structure, and thus the arrangement is orderly, so as to further improve the light-emitting effect of the first sub-pixel.

Optionally, in the first direction, the first sub-pixel block, the second sub-pixel block, and the third sub-pixel block are of a same length, so that the first sub-pixel block, the second sub-pixel block, and the third sub-pixel block have similar light-emitting dimensions in the first direction to further improve the light-emitting effect of the first sub-pixel.

Optionally, in the second direction, a side edge of the first sub-pixel block away from the second sub-pixel block is flush with one side edge of the third sub-pixel block, and thus the arrangement is orderly, so as to further improve the light-emitting effect of the first sub-pixel. Optionally, in the second direction, a side edge of the second sub-pixel block away from the first sub-pixel block is flush with one side edge of the third sub-pixel block, and thus the arrangement is orderly, so as to further improve the light-emitting effect of the first sub-pixel.

In at least one embodiment of the present application, the first sub-pixel includes four sub-pixel blocks (e.g., sub-pixel blocks R1, R2, R3, and R4 in FIG. 25) arranged circularly, i.e., the four sub-pixel blocks are staggered and arranged in different directions, and the four sub-pixel blocks surround a center and arranged around the center. For example, for a sub-pixel block, one sub-pixel block is arranged at each side of the sub-pixel block in the first direction and the second direction, and the four sub-pixel blocks are arranged in an array in the first direction and in the second direction.

Optionally, in the first direction and/or the second direction, at least two adjacent sub-pixel blocks are of a same length and have two flush side edges to form a rectangular structure, so that the various sub-pixel blocks have similar light-emitting dimensions in the first direction and the second direction to further improve the light-emitting effect of the first sub-pixel. The first sub-pixel block and the second sub-pixel block form a rectangular structure, i.e., the outer contours of the first sub-pixel block and the second sub-pixel block are extended and connected to form a rectangular structure, and thus the arrangement is orderly, so as to further improve the light-emitting effect of the first sub-pixel.

In at least one embodiment of the present application, in the first sub-pixel, orthographic projections of at least two sub-pixel blocks on the base 100 are of a same size, so that the various sub-pixel blocks in the first sub-pixel have similar light-emitting dimensions to further improve the light-emitting effect of the first sub-pixel. The orthographic projections of two sub-pixel blocks on the base 100 being of a same size means that the two sub-pixel blocks have the same shape and the same sizes in both the first direction and the second direction. For example, the orthographic projection of one sub-pixel block on the base 100 may be obtained by shifting or rotating the orthographic projection of another sub-pixel block on the base 100.

Optionally, the first sub-pixel includes 2n sub-pixel blocks, in which n is a positive integer, and the orthographic projections of the various sub-pixel blocks on the base 100 are of a same size, i.e., the first sub-pixel is divided into an even number of sub-pixel blocks, and the various sub-pixel blocks have similar light-emitting dimensions to further improve the light-emitting effect of the first sub-pixel.

Optionally, an orthographic projection of at least one of the sub-pixel blocks of the first-color sub-pixel on the base 100 has the same size as an orthographic projection of one of the sub-pixel blocks of the second-color sub-pixel on the base 100, i.e., at least one sub-pixel block of the first-color sub-pixel has similar light-emitting dimension with the sub-pixel block of the second-color sub-pixel, so as to improve the light-emitting uniformity of the first-color sub-pixel and the second-color sub-pixel.

In at least one embodiment of the present application, an orthographic projection of the first sub-pixel on the base 100 is a polygon in shape, the polygon includes a plurality of corner areas, and at least one of the corner areas is provided with the sub-pixel block. For example, the orthographic projection of the first sub-pixel on the base 100 is a rectangle in shape, the rectangle includes four corner areas, and at least one sub-pixel block is located within one of the corner areas. Optionally, the first sub-pixel includes three sub-pixel blocks, in which two of the sub-pixel blocks are located within two of the corner areas, respectively, and the other sub-pixel block is arranged across the other two corner areas. Optionally, the first sub-pixel includes four sub-pixel blocks which are located within the four corner areas, respectively. With the sub-pixel blocks being located within the corner areas, the light-emitting effect of the first sub-pixel can be improved, thereby improving the display effect of the display panel.

Optionally, as shown in FIGS. 25 and 26, an orthographic projection of the sub-pixel block on the base 100 includes straight edges and/or curved edges. For example, the orthographic projection of the sub-pixel block on the base 100 includes only straight edges, as shown in FIG. 25, or the orthographic projection of the sub-pixel block on the base 100 includes only curved edges. Alternatively, as shown in FIG. 26, the orthographic projection of the sub-pixel block on the base 100 includes a combination of straight edges and curved edges.

Optionally, at least two of the straight edges are perpendicular to form a right angle. The sub-pixel block includes a right angle, so that the outer contour of the first sub-pixel includes a right angle, and the first sub-pixel with a right angle is easily manufactured and has good light-emitting effect.

Optionally, as shown in FIG. 26, for at least two adjacent sub-pixel blocks, the right angles of the two sub-pixel blocks are arranged away from each other, so that the right angles of the sub-pixel blocks are all located on the outer contour, i.e., the outer contour of the first sub-pixel has right angles, so that the first sub-pixel is easily manufactured and has good light-emitting effect.

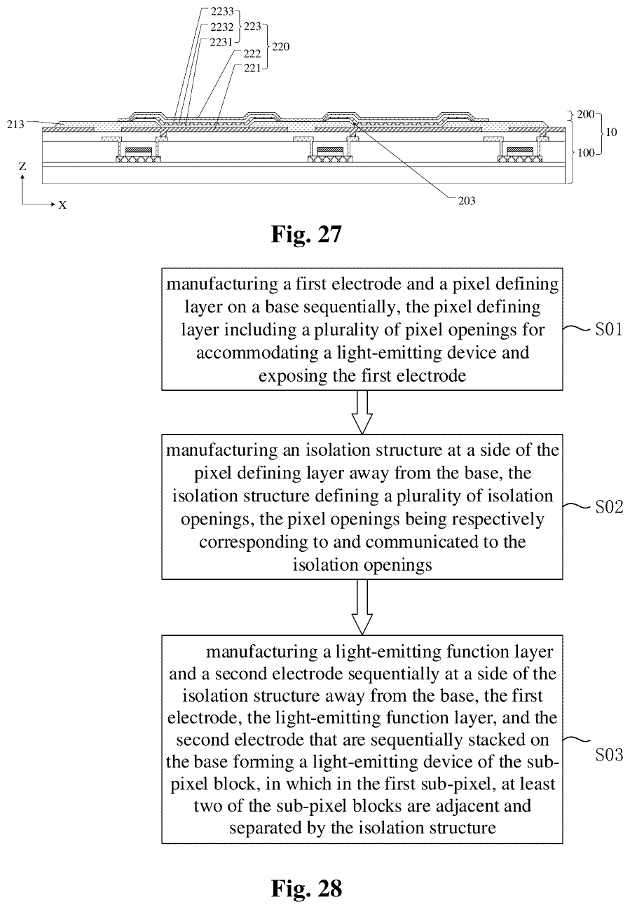

As shown in FIG. 27, at least one embodiment of the present application provides a display panel including a first display area, in which the first display area includes a plurality of first sub-pixels arranged in an array in a first direction, the first sub-pixel includes at least two sub-pixel blocks that are spaced apart from each other, the display panel further includes a pixel defining layer 213 located at a side of the base 100 and including a plurality of pixel openings 203, the light-emitting devices 220 of the sub-pixel blocks are located within the pixel openings 203, and in the first sub-pixel, at least two of the sub-pixel blocks are adjacent and separated by the pixel defining layer 213. In the display panel, by dividing the first sub-pixel into a plurality of sub-pixel blocks, debris may cause poor light emission in only one of the sub-pixel blocks, while the first sub-pixel itself can still emit light, thereby reducing the risk that hazardous substances such as debris intrude into the sub-pixel and cause display malfunction in the display panel. Moreover, the first sub-pixel is divided, by the pixel defining layer 213, into a plurality of sub-pixel blocks that are spaced apart from each other, and thus no isolation structure 210 is required and the manufacturing process is simplified.

Still referring to FIG. 3, in at least one embodiment of the present application, the display panel further includes an isolation structure 210 located at a side of the pixel defining layer 213 away from the base and defining a plurality of isolation openings 202, the light-emitting devices 220 of the sub-pixel blocks are respectively disposed in the isolation openings 202, the pixel openings 203 are respectively corresponding to the isolation openings 202, and the pixel opening 203 is communicated to a corresponding one of the isolation openings 202.

In at least one embodiment of the present application, in the first sub-pixel, at least two of the sub-pixel blocks are adjacent and separated by the isolation structure 210. Both the pixel defining layer 213 and the isolation structure 210 are used to divide the first sub-pixel to improve the dividing effect for the first sub-pixel, so that the adjacent sub-pixel blocks will not affect each other.

Still referring to FIG. 7, in at least one embodiment of the present application, in the first sub-pixel, an orthographic projection of the pixel openings 203 corresponding to at least two sub-pixel blocks on the base 100 is located within an orthographic projection of a same isolation opening 202 on the base 100. The pixel opening 203 corresponding to the sub-pixel block is the pixel opening 203 in which the light-emitting device 220 of the sub-pixel block is located, and the first sub-pixel as a whole is partitioned by the isolation structure 210, so that the light-emitting function layers 223 of the various sub-pixel blocks in the first sub-pixel are located within the same isolation opening 202, i.e., it is not necessary to arrange the isolation structure 210 between the various sub-pixel blocks of the first sub-pixel, while the sub-pixel blocks of the first sub-pixel are spaced apart from each other only by the pixel defining layer 213, and thus the overall difficulty for manufacturing the isolation structure 210 is reduced. Moreover, the sub-pixel blocks in the same first sub-pixel emit lights of the same color, and thus color mixing problem caused by carrier crosstalk will not occur among the light-emitting function layers 223 of the various sub-pixel blocks. Therefore, even if the isolation structure 210 is not arranged between the sub-pixel blocks of the same first sub-pixel, the light-emitting effect of the first sub-pixel can still be ensured.

Still referring to FIG. 3, in at least one embodiment of the present application, an orthographic projection of the pixel opening 203 corresponding to each the sub-pixel block on the base 100 is located within an orthographic projection of the isolation opening 202 on the base 100. The sub-pixel blocks are all separated by the isolation structure 210, i.e., the sub-pixel blocks are separated directly by the isolation structure 210, and thus no other mask plate is required for manufacturing the sub-pixel blocks, and the cost is reduced. Moreover, the isolation structure 210 provides good separating effect, so that the light-emitting function layers 223 of the various sub-pixel blocks are insulated from each other and do not affect each other. The first sub-pixel is divided into a plurality of independent sub-pixel blocks, so that when at least one of the sub-pixel blocks is damaged and causes dark spot, the other sub-pixel blocks continue to emit light normally, so as to ensure that the display panel emits light normally. That is, the division of the first sub-pixel into a plurality of sub-pixel blocks can reduce the effect of single dark spot on the display of the display panel.

At least one embodiment of the present application provides a display apparatus that may include the display panel in the above embodiments. Furthermore, under a condition that the first display area is a recognition area, the display apparatus may include a photosensitive device, and an orthographic projection of the photosensitive device on the base at least partially overlaps the first display area.

For example, in some embodiments of the present application, the photosensitive device includes at least one fingerprint recognition sensor. For example, the fingerprint recognition sensor may be arranged at a side of the base away from the display function layer or within the base.

For example, in some other embodiments of the present application, the photosensitive device may be a camera located at a side of the base away from the display function layer.

For example, in the embodiments of the present application, the display apparatus may be a television, a digital camera, a cellular phone, a watch, a tablet computer, a laptop computer, a navigator, and any other product or component with display function.

As shown in FIG. 28, and with reference to FIGS. 1 to 27, at least one embodiment of the present application provides a method for manufacturing a display panel including a first display area, the first display area includes a plurality of first sub-pixels arranged in an array in a first direction, the first sub-pixel includes at least two sub-pixel blocks, the method includes:
Step S01: manufacturing a first electrode and a pixel defining layer on a base sequentially, the pixel defining layer including a plurality of pixel openings for accommodating a light-emitting device and exposing the first electrode;
Step S02: manufacturing an isolation structure at a side of the pixel defining layer away from the base, the isolation structure defining a plurality of isolation openings, the pixel openings being respectively corresponding to and connected to the isolation openings;
Step S03: manufacturing a light-emitting function layer and a second electrode sequentially at a side of the isolation structure away from the base, the first electrode, the light-emitting function layer, and the second electrode that are sequentially stacked on the base forming a light-emitting device of the sub-pixel block, in which in the first sub-pixel, at least two of the sub-pixel blocks are adjacent and separated by the isolation structure.

In these embodiments, the first electrode 221 and the pixel defining layer 213 are manufactured by step S01; the isolation structure 210 is manufactured by step S02; the light-emitting function layer 223 and the second electrode 222 are manufactured by step S03, and the first electrode 221, the light-emitting function layer 223, and the second electrode 222 form the light-emitting device 220 of the sub-pixel block. The sub-pixel blocks are all separated by the isolation structure 210, i.e., the sub-pixel blocks are separated directly by the isolation structure 210, and thus no other mask plate is required for manufacturing the sub-pixel blocks, and the cost is reduced. Moreover, the isolation structure 210 provides good separating effect, so that the light-emitting function layers 223 of the various sub-pixel blocks are insulated from each other and do not affect each other. The first sub-pixel is divided into a plurality of independent sub-pixel blocks, so that when at least one of the sub-pixel blocks is damaged and causes dark spot, the other sub-pixel blocks continue to emit light normally, so as to ensure that the display panel emits light normally. That is, the division of the first sub-pixel into a plurality of sub-pixel blocks can reduce the effect of single dark spot on the display of the display panel.

In at least one embodiment of the present application, the first display area further includes a plurality of second-color sub-pixels and a plurality of third-color sub-pixels that are arranged in an array in the first direction, adjacent first-color sub-pixel, second-color sub-pixel, and third-color sub-pixel constitute a pixel, the method further includes: manufacturing the light-emitting device 220 of the first-color sub-pixel on the base 100, the first-color sub-pixel including a sub-pixel blocks; and manufacturing the light-emitting device 220 of the second-color sub-pixel on the base 100, the second-color sub-pixel including b sub-pixel blocks, in which a and b satisfy a>b.

In these embodiments, if the first-color sub-pixel, the second-color sub-pixel, and the third-color sub-pixel are each divided into a plurality of sub-pixel blocks, the first-color sub-pixel, the second-color sub-pixel, and the third-color sub-pixel include the same number of sub-pixel blocks, the number distribution is regular to improve the display uniformity of the display panel, and the arrangement of the isolation structure 210 is relatively regular to reduce the difficulty for manufacturing the isolation structure 210. If a is greater than b, i.e., the number of the sub-pixel blocks of the first-color sub-pixel is greater than the number of the sub-pixel blocks of the second-color sub-pixel, and for example, the first-color sub-pixel includes four sub-pixel blocks, the second-color sub-pixel includes three sub-pixel blocks, the third-color sub-pixel includes two sub-pixel blocks; in the first-color sub-pixel, the number of the sub-pixel blocks is greater and the area of an individual sub-pixel block is smaller, and when at least one of the sub-pixel blocks suffers from dark spot problem, the other sub-pixel blocks emit light normally and have a larger light-emitting area, i.e., the first-color sub-pixel has a greater aperture rate, thereby reducing the effect of single dark spot on the display of the display panel. If the manufacturing of the first-color sub-pixel is after the evaporation of the second-color sub-pixel, the first-color sub-pixel is more vulnerable to dark spot problem, and thus the first-color sub-pixel is divided into a greater number of sub-pixel blocks, so as to further reduce the effect of the dark spot problem on the display. That is, the first sub-pixel that is latterly manufactured is divided into a greater number of sub-pixel blocks, so as to balance the influence from dark spots on the first sub-pixels of various colors to ensure the overall display effect of the display panel.

In at least one embodiment of the present application, after the manufacturing the light-emitting device 220 of the second-color sub-pixel on the base 100, the method further includes: manufacturing the light-emitting device 220 of the third-color sub-pixel on the base 100, the third-color sub-pixel including c sub-pixel blocks, in which b and c satisfy b>c.

In these embodiments, the structure and effect of the second-color sub-pixel and the third-color sub-pixel are the same as those of the first-color sub-pixel and the second-color sub-pixel, and will not be repeated herein. For example, the first-color sub-pixel, the second-color sub-pixel, and the third-color sub-pixel are sub-pixel R, sub-pixel G, and sub-pixel B, respectively; or the first-color sub-pixel, the second-color sub-pixel, and the third-color sub-pixel are sub-pixel R, sub-pixel B, and sub-pixel G, respectively; or the first-color sub-pixel, the second-color sub-pixel, and the third-color sub-pixel are sub-pixel G, sub-pixel R, and sub-pixel B, respectively; or the first-color sub-pixel, the second-color sub-pixel, and the third-color sub-pixel are sub-pixel G, sub-pixel B, and sub-pixel R, respectively; or the first-color sub-pixel, the second-color sub-pixel, and the third-color sub-pixel are sub-pixel B, sub-pixel G, and sub-pixel R, respectively; or the first-color sub-pixel, the second-color sub-pixel, and the third-color sub-pixel are sub-pixel B, sub-pixel R, and sub-pixel G, respectively.

The foregoing is merely to provide preferred embodiments of the specification and not intended to limit the specification, and any modification, equivalent substitution, etc., made within the gist and principle of the specification shall be encompassed within the scope of protection of the specification.

What is claimed is:

1. A display panel comprising a first display area, wherein the first display area comprises a plurality of first sub-pixels arranged in an array in a first direction, the first sub-pixel comprises at least two sub-pixel blocks; and
in the first sub-pixel, at least two of the sub-pixel blocks are adjacent and separated by an isolation structure.

2. The display panel according to claim 1, further comprising a base and a display function layer located on the base in a second direction, wherein the display function layer comprises a plurality of light-emitting devices, and each of the sub-pixel blocks is provided with one of the light-emitting devices; the light-emitting device comprises a first electrode, a light-emitting function layer, and a second electrode sequentially stacked on the base, and in a same first sub-pixel, the first electrodes respectively corresponding to adjacent sub-pixel blocks are electrically connected to each other; the isolation structure is located on the base and defines a plurality of isolation openings, and the light-emitting devices are respectively disposed in the isolation openings.

3. The display panel according to claim 2, wherein the isolation structure comprises a support portion and a crown portion sequentially stacked on the base, an orthographic projection of the support portion on the base is located within an orthographic projection of the crown portion on the base, and
the support portion comprises a conductive structure, and the second electrode of the light-emitting device is located in a corresponding one of the isolation openings and connected to the support portion; and
wherein the support portion and the crown portion are integrally manufactured; or the support portion and the crown portion are of different materials.

4. The display panel according to claim 3, wherein the base further comprises:
a pixel defining layer located at a side of the isolation structure close to the base and comprising a plurality of pixel openings respectively corresponding to the isolation openings;
wherein the pixel opening accommodates the light-emitting device and exposes the first electrode, the pixel openings are respectively corresponding to the isolation openings, and the pixel opening is communicated to a corresponding one of the isolation openings.

5. The display panel according to claim 4, wherein in the first sub-pixel, an orthographic projection of the pixel openings corresponding to at least two of the sub-pixel blocks on the base is located within an orthographic projection of a same isolation opening on the base; or
an orthographic projection of the pixel opening corresponding to each of the sub-pixel blocks on the base is located within an orthographic projection of the isolation opening on the base; and
wherein an orthographic projection of a gap between two adjacent first electrodes on the base is located within an orthographic projection of the support portion on the base to overlap edges of the first electrodes with edges of the support portion to form a capacitor, and the pixel defining layer covers the edges of the first electrodes to separate the support portion and the first electrodes.

6. The display panel according to claim 2, wherein the isolation structure extends continuously between two adjacent sub-pixel blocks as a mesh to block light between the two adjacent sub-pixel blocks by the isolation structure; and
wherein in the first display area, the isolation structure further defines a plurality of light-transmitting openings located between the sub-pixel blocks of the first sub-pixel.

7. The display panel according to claim 6, further comprising a touch control structure located at a light-emitting side of the base and comprising a plurality of touch control electrodes formed as a mesh, and an orthographic projection of a mesh line of the mesh of the touch control electrode on the base is located in a gap between adjacent first sub-pixels.

8. The display panel according to claim 7, wherein
an orthographic projection of the first electrode on the base is located outside an orthographic projection of the light-transmitting opening on the base, a wire is arranged in the base, and in the first sub-pixel, the first electrodes of the light-emitting devices corresponding to two adjacent sub-pixel blocks are connected to each other via the wire; or
in the first sub-pixel, the light-emitting devices corresponding to two adjacent sub-pixel blocks share the first electrode; or
the first electrode comprises a reflective electrode layer and a transparent electrode layer stacked on the base, and the reflective electrode layer is located between the base and the transparent electrode layer; in the first sub-pixel, the first electrodes of the light-emitting devices in the sub-pixel blocks are connected via the transparent electrode layer, and the orthographic projection of the light-transmitting opening on the base is located within an orthographic projection of the transparent electrode layer on the base.

9. The display panel according to claim 6, wherein the first sub-pixel emits light of at least one color elected from red, green, or blue, and
the first sub-pixel is a first-color sub-pixel emitting light of one color, the first display area further comprises a plurality of second-color sub-pixels and a plurality of third-color sub-pixels that are arranged in an array in the first direction, adjacent first-color sub-pixel, second-color sub-pixel, and third-color sub-pixel constitute a pixel; in each pixel, the first-color sub-pixel is located between the second-color sub-pixel and the third-color sub-pixel, and the second-color sub-pixel and the third-color sub-pixel each comprise a continuous structure; along a direction from the second-color sub-pixel to the third-color sub-pixel, a width of the first-color sub-pixel is equal to a width of the light-transmitting opening, and wavelengths of lights emitted by the second-color sub-pixel, the first-color sub-pixel, and the third-color sub-pixel decrease successively; or
the first sub-pixel is categorized as at least a first-color sub-pixel and a second-color sub-pixel that emit lights of two colors, respectively, the first display area further comprises a plurality of third-color sub-pixels arranged in an array in the first direction, every adjacent first-color sub-pixel, second-color sub-pixel, and third-color sub-pixel constitute a pixel; in each pixel, the second-color sub-pixel is located between the first-color sub-pixel and the third-color sub-pixel, and the third-color sub-pixel comprises a continuous structure; in each pixel, the light-transmitting openings corresponding to the first-color sub-pixel and the second-color sub-pixel are communicated to each other; at a side of the first-color sub-pixel away from the second-color sub-pixel, a distance from the light-transmitting opening to a mesh line is greater than a distance from the first-color sub-pixel to the mesh line, and wavelengths of lights emitted by the first-color sub-pixel, the second-color sub-pixel, and the third-color sub-pixel decrease successively; or
the first sub-pixel is categorized as at least a first-color sub-pixel, a second-color sub-pixel, and a third-color sub-pixel that emit lights of three colors, respectively, every adjacent first-color sub-pixel, second-color sub-pixel, and third-color sub-pixel constitute a pixel; in each pixel, the second-color sub-pixel is located between the first-color sub-pixel and the third-color sub-pixel; in each pixel, the light-transmitting openings corresponding to the first-color sub-pixel, the second-color sub-pixel, and the third-color sub-pixel are communicated to each other; at a side of the first-color sub-pixel away from the second-color sub-pixel, a distance from the light-transmitting opening to a mesh line is greater than a distance from the first-color sub-pixel to the mesh line, and at a side of the third-color sub-pixel away from the second-color sub-pixel, a distance from the light-transmitting opening to the mesh line is greater than a distance from the third-color sub-pixel to the mesh line; wavelengths of lights emitted by the first-color sub-pixel, the second-color sub-pixel, and the third-color sub-pixel decrease successively.

10. The display panel according to claim 7, wherein
the touch control electrode comprises a plurality of mesh holes enclosed by mesh lines and corresponding to the first sub-pixels in one-to-one correspondence, the first sub-pixel is located within an orthographic projection of a corresponding one of the mesh holes on the base, and a centroid of the orthographic projection of the mesh hole on the base coincides with a centroid of the first sub-pixel; or
the touch control electrode comprises a plurality of mesh holes enclosed by mesh lines and corresponding to pixels in one-to-one correspondence, the pixel is located within an orthographic projection of a corresponding one of the mesh holes on the base, and a centroid of the orthographic projection of the mesh hole on the base coincides with a centroid of a corresponding one of the pixels.

11. The display panel according to claim 10, wherein the touch control electrode comprises a plurality of first electrode strips that are parallel to each other and a plurality of second electrode strips that are parallel to each other, the first electrode strips and the second electrode strips intersect and are arranged as the mesh of the touch control electrode.

12. The display panel according to claim 6, further comprising a second display area, and a light transmittance of the first display area being greater than a light transmittance of the second display area.

13. The display panel according to claim 1, wherein the first sub-pixel comprises a first-color sub-pixel, a second-color sub-pixel, and a third-color sub-pixel that are spaced apart from each other and of different colors, and the first-color sub-pixel, the second-color sub-pixel, and the third-color sub-pixel are arranged adjacently;
the second-color sub-pixel is located at one side of the first-color sub-pixel in a second direction, the third-color sub-pixel is located at one side of the first-color sub-pixel in the first direction, and the first direction is intersected with the second direction;
in the first direction, the first-color sub-pixel and the second-color sub-pixel are of a same length and have two flush side edges to form a rectangular structure;
in the first direction, the first-color sub-pixel, the second-color sub-pixel, and the third-color sub-pixel are of a same length;
in the second direction, one side edge of the first-color sub-pixel is flush with one side edge of the third-color sub-pixel;
in the second direction, one side edge of the second-color sub-pixel is flush with one side edge of the third-color sub-pixel;
the first-color sub-pixel, the second-color sub-pixel, and the third-color sub-pixel are long strip in shape and sequentially arranged at intervals in the first direction; and
in a second direction intersecting the first direction, the first-color sub-pixel, the second-color sub-pixel, and the third-color sub-pixel are of a same length and have two flush side edges to form a rectangular structure.

14. The display panel according to claim 13, wherein the first sub-pixel comprises at least three sub-pixel blocks, and a plurality of the sub-pixel blocks are arranged circularly;
in the first sub-pixel, for a same sub-pixel block, at least one of the sub-pixel blocks is arranged at each side of the sub-pixel block in the first direction and the second direction; and
wherein the isolation structure extends along the first direction and the second direction, and the first sub-pixel separates, through the isolation structure, the sub-pixel blocks that are adjacent in the first direction or the sub-pixel blocks that are adjacent in the second direction.

15. The display panel according to claim 13, wherein the first-color sub-pixel comprises a sub-pixel blocks, the second-color sub-pixel comprises b sub-pixel blocks, the third-color sub-pixel comprises c sub-pixel blocks, and a, b, and c satisfy a≥b≥c.

16. The display panel according to claim 15, wherein a, b, and c satisfy a>b>c.

17. The display panel according to claim 13, wherein the first sub-pixel comprises two sub-pixel blocks arranged at intervals along the first direction; and
in the second direction, the two sub-pixel blocks are of a same length and have two flush side edges to form a rectangular structure.

18. The display panel according to claim 13, wherein the first sub-pixel comprises a first sub-pixel block, a second sub-pixel block, and a third sub-pixel block, the first sub-pixel block and the second sub-pixel block are located at one side of the third sub-pixel block in the first direction, and the first sub-pixel block and the second sub-pixel block are arranged at intervals in the second direction;
in the first direction, the first sub-pixel block and the second sub-pixel block are of a same length and have two flush side edges to form a rectangular structure;
in the first direction, the first sub-pixel block, the second sub-pixel block, and the third sub-pixel block are of a same length;
in the second direction, a side edge of the first sub-pixel block away from the second sub-pixel block is flush with one side edge of the third sub-pixel block; and
in the second direction, a side edge of the second sub-pixel block away from the first sub-pixel block is flush with one side edge of the third sub-pixel block.

19. The display panel according to claim 13, wherein the first sub-pixel comprises four sub-pixel blocks arranged circularly; and
in the first direction or the second direction, at least two adjacent sub-pixel blocks are of a same length and have two flush side edges to form a rectangular structure.

20. The display panel according to claim 13, wherein in the first sub-pixel, orthographic projections of at least two of the sub-pixel blocks on a base are of a same size; and
an orthographic projection of at least one of the sub-pixel blocks of the first-color sub-pixel on the base has the same size as an orthographic projection of one of the sub-pixel blocks of the second-color sub-pixel on the base.

21. The display panel according to claim 2, wherein an orthographic projection of the first sub-pixel on the base is a polygon in shape, the polygon comprises a plurality of corner areas, and at least one of the corner areas is provided with the sub-pixel block; and
wherein an orthographic projection of the sub-pixel block on the base comprises straight edges or curved edges;
at least two of the straight edges are perpendicular to form a right angle; and
for at least two adjacent sub-pixel blocks, the right angles of the two sub-pixel blocks are arranged away from each other.

22. A display panel comprising:
a first display area;
a plurality of first sub-pixels arranged in an array in a first direction and disposed in the first display area, and the first sub-pixel comprising at least two sub-pixel blocks that are spaced apart from each other;
a base; and
a pixel defining layer located at a side of the base and comprising a plurality of pixel openings, and a plurality of light-emitting devices of the sub-pixel blocks being located within the pixel openings;
wherein in the first sub-pixel, at least two of the sub-pixel blocks are adjacent and separated by the pixel defining layer.

23. The display panel according to claim 22, further comprising:
an isolation structure located at a side of the pixel defining layer away from the base and defining a plurality of isolation openings, the light-emitting devices of the sub-pixel blocks being respectively disposed in the isolation openings, the pixel openings being respectively corresponding to the isolation openings, and the pixel opening being communicated to a corresponding one of the isolation openings; and
in the first sub-pixel, at least two of the sub-pixel blocks being adjacent and separated by the isolation structure.

24. The display panel according to claim 23, wherein in the first sub-pixel, an orthographic projection of the pixel openings corresponding to at least two of the sub-pixel blocks on the base is located within an orthographic projection of a same isolation opening on the base; or
an orthographic projection of the pixel opening corresponding to each of the sub-pixel blocks on the base is located within an orthographic projection of the isolation opening on the base.

25. A display apparatus, comprising the display panel according to claim 1.
